(19) United States
(12) Patent Application Publication
(10) Pub. No.: US 2015/0262546 A1
(43) Pub. Date: Sep. 17, 2015

(54) DISPLAY DEVICE AND DISPLAY METHOD

(71) Applicant: Toppan Printing Co., Ltd., Taito-ku (JP)

(72) Inventors: Jun OGURA, Taito-ku (JP); Masanori Sakamoto, Taito-ku (JP)

(73) Assignee: Toppan Printing Co., Ltd., Taito-ku (JP)

(21) Appl. No.: 14/728,581

(22) Filed: Jun. 2, 2015

Related U.S. Application Data
(63) Continuation of application No. PCT/JP2013/081493, filed on Nov. 22, 2013.

(30) Foreign Application Priority Data
Dec. 7, 2012 (JP) 2012-268292

(51) Int. Cl. G09G 5/00; G09G 5/18; G06T 1/60; G09G 3/30

(52) U.S. Cl. CPC G09G 5/003; G09G 3/30; G09G 5/18; G06T 1/60; G09G 2300/0426

(57) ABSTRACT

A display device includes pixel circuits each including a transistor and supplies a drive current to each light emitting element, scan lines and data lines connected to the pixel circuits, a select driver which selects a scan lines, and a control unit which controls driving of the select driver. The control unit repeatedly executes a gradation display operation, a non-gradation display operation and a detecting operation in the order. In the gradation display operation, a gradation display voltage is applied to the pixel circuit connected to a selected scan line. In the non-gradation display operation, a non-gradation display voltage is applied to the pixel circuit connected to a selected scan line. In the detecting operation, a characteristic of the transistor of the pixel circuit connected to one or more scan lines is detected to correct the gradation display voltage based on a detection result of the detecting operation.

### CROSS-REFERENCE TO RELATED APPLICATIONS

The present application is a continuation of International Application No. PCT/JP2013/081493, filed Nov. 22, 2013, which is based upon and claims the benefits of priority to Japanese Application No. 2012-268292, filed Dec. 7, 2012. The entire contents of these applications are incorporated herein by reference.

### BACKGROUND OF THE INVENTION

1. Field of the Invention

A technique according to the present disclosure relates to a display device provided with light emitting elements to which drive current is supplied via transistors, and a display method.

2. Discussion of the Background

A display device described in patent literatures 1 and 2 sequentially drives a plurality of electroluminescent elements (EL element) arranged in a matrix by scanning a scan line. In the display device described in the patent literature 1, two transistors including a current control transistor and a sampling transistor, arranged for every organic EL element, control a drive current to be supplied to a respective plurality of organic EL elements which are connected to one scan line. Every time the sampling transistor switches to a conduction state, voltage corresponding to display data is applied between gate and source of the current control transistor. Hence, drain current corresponding to the voltage between gate and source of the current control transistor, as a drive current, is supplied to the organic EL element so that the gradation of light luminance is controlled for every organic EL element.
Patent literature 1: Japanese Patent Application Laid-Open Publication Number 1996-330600
Patent literature 2: Japanese Patent Application Laid-Open Publication Number 2010-128397

### SUMMARY OF THE INVENTION

According to one aspect of the present invention, a display device includes light emitting elements, pixel circuits each including a transistor and supplies a drive current to each of the light emitting elements, scan lines connected to the pixel circuits, data lines connected to the pixel circuits, a select driver which selects one of the scan lines; and a control unit which controls driving of the select driver. The control unit repeatedly executes a set of operations including a gradation display operation, a non-gradation display operation and a detecting operation in an order thereof. The gradation display operation is an operation in which the scan lines are sequentially selected one by one, and a gradation display voltage is applied to the pixel circuit connected to a selected scan line via one of the data lines such that a corresponding light emitting element has a gradation display state. The non-gradation display operation is an operation in which the scan lines are sequentially selected one by one, and a non-gradation display voltage is applied to the pixel circuit connected to a selected scan line via one of the data lines such that a corresponding light emitting element has a non-gradation display state. The detecting operation is an operation in which one or more scan lines are selected in the non-gradation display operation, and a characteristic of the transistor of the pixel circuit connected to the one or more scan lines is detected via one of the data lines to correct the gradation display voltage based on a detection result of the detecting operation.

According to another aspect of the present invention, a display method includes repeatedly executing a set of operations including a gradation display operation, a non-gradation display operation and a detecting operation in an order thereof, and correcting a gradation display voltage based on a detection result of the detecting operation. The gradation display operation is an operation in which the scan lines are sequentially selected one by one, and a gradation display voltage is applied to the pixel circuit connected to a selected scan line via one of the data lines such that a corresponding light emitting element has a gradation display state. The non-gradation display operation is an operation in which the scan lines are sequentially selected one by one, and a non-gradation display voltage is applied to the pixel circuit connected to a selected scan line via one of the data lines such that a corresponding light emitting element has a non-gradation display state. The detecting operation is an operation in which one or more scan lines are selected in the non-gradation display operation, and a characteristic of the transistor of the pixel circuit connected to the one or more scan lines is detected via one of the data lines to correct the gradation display voltage based on a detection result of the detecting operation.

### BRIEF DESCRIPTION OF DRAWINGS

A more complete appreciation of the invention and many of the attendant advantages thereof will be readily obtained as the same becomes better understood by reference to the following detailed description when considered in connection with the accompanying drawings, wherein:

FIG. 1 is a block diagram showing an overall configuration of a display device according to the first embodiment;

FIG. 2 is a block diagram showing a functional configuration of a control unit in the display device as shown in FIG. 1 in a functional manner;

FIG. 3 is a circuit diagram showing a configuration of a pixel circuit in the display device as shown in FIG. 1 and a configuration of a data driver;

FIG. 4 is a graph showing a relationship between display voltage applied to the pixel circuit as shown in FIG. 3 and drain current of a current control transistor;

FIG. 5 is a timing diagram showing a change in signal level of respective control signals in a threshold detecting operation of the display device as shown in FIG. 1 together with states of respective switches;

FIG. 6 is a graph showing a relationship between electric potential of a data line in the display device as shown in FIG. 1 and a relaxation time;

FIG. 7 is a timing diagram showing a change in signal level of respective control signals in a display operation period of the display device as shown in FIG. 1 together with states of respective switches;

FIG. 8 is a diagram schematically showing timings of various operations, for respective pixels from the 1st row to the 540^{th} row, executed in the first frame of the display device of FIG. 1;

FIG. 9 is a diagram schematically showing timings of various operations, for respective pixels from the 1st row to the 540^{th} row, executed in the second frame of the display device of FIG. 1;

FIG. 10 is a diagram schematically showing timings of various operations, for respective pixels from the 1st row to the 540^{th} row, executed in the second frame of the display device of FIG. 1;

FIG. 11 is a timing diagram showing a change in signal level of respective control signals in a period where one frame of the display device of FIG. 1 is displayed for every scan line and power line;

FIG. 12 is a diagram schematically showing a change in row number to be detected in a threshold detecting operation for each frame according to the second embodiment;

FIG. 13 is a diagram schematically showing a change in row number to be detected in a threshold detecting operation for each frame according to the second embodiment; and

FIG. 14 is a diagram schematically showing a change in row number to be detected in a threshold detecting operation for each frame according to the second embodiment.

### DESCRIPTION OF THE EMBODIMENTS

The embodiments will now be described with reference to the accompanying drawings, wherein like reference numerals designate corresponding or identical elements throughout the various drawings.

### First Embodiment

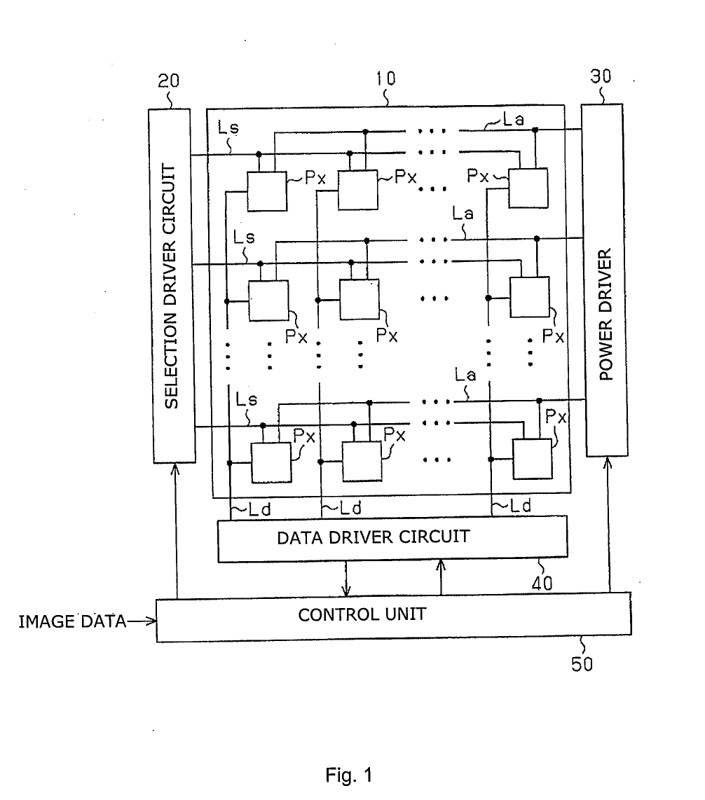

With reference to FIGS. 1 to 11, a display device according to the first embodiment will be described.

The display device of the present embodiment employs an active matrix drive method and allows an organic EL element to be illuminated as a light emitting element. A display operation corresponding to one frame in the display device includes a gradation display operation in which an image based on the display data is displayed and a black display operation in which a black image is displayed. In this case, in a period in which the black display operation is performed, voltage relative to a threshold voltage of a current control transistor included in the pixel circuit is detected for each of a plurality of pixels which are connected to a specific scan line, and a display voltage applied to the pixel circuit based on the display data is corrected by using a detection result concerning the threshold voltage. In other words, in a period in which one frame is displayed, a display operation where the gradation display operation and the black display operation are performed alternately and repeatedly and a threshold detecting operation where voltage concerning the threshold voltage is detected are included. It should be noted that the black display operation corresponds to a non-gradation display operation and the threshold detecting operation corresponds to a detecting operation. In the followings, these display operation and threshold detecting operation will be mainly described.

Configuration of Display Device

With reference to FIG. 1, an overall configuration of the display device is described. As shown in FIG. 1, in a display panel 10, a plurality of pixels Px are arranged in a matrix having m rows and n columns, where m is one or more and integer number and n is also one or more and integer number. In each of the plurality of pixels Px, one organic EL element and one pixel circuit that supplies the one organic EL element with drive current are arranged.

Each of the plurality of pixels Px is arranged near a cross point at which one line among m scan lines Ls which extend in a row direction and one line among n data lines Ld which extend in a column direction cross with each other in planar view. The n number of pixels Px arranged along the row direction are connected to a common scan line Ls and a common power line La. The m number pixels Px arranged along the column direction are connected to a common data line Ld.

Each of the m scan lines Ls is connected to a select driver circuit 20, each of the power lines La is connected to a power driver 30 and each of the n data lines Ld is connected to a data driver circuit 40. Each of the select driver circuit 20, the power driver 30 and the data driver circuit 40 are driven by a control unit 50. The control unit 50 is configured by mainly a microcomputer having a central processing unit and a memory unit. The control unit 50 generates display data by using image data received by the control unit 50.

The select driver circuit 20 is configured by, for example, a shift register and a buffer. The select driver circuit 20 applies either high level selection voltage VgH or low level selection voltage VgL for every scan line Ls in response to a control signal from the control unit 50. The select driver circuit 20 determines the scan line Ls to which the selection voltage VgH is applied to be a selected object and sequentially switches candidate of the selected object from a scan line Ls in the first row to a scan line Ls of m th row which is the last row.

The power driver 30 is configured by, for example, a shift register and a buffer. The power driver 30 applies, in response to a control signal from the control unit 50, either high level drive voltage ELVDD or low level write voltage WDVSS to respective power lines La. The power driver 30 switches an object row to which the drive voltage ELVDD is applied, from a power line La of the first row to a power line La of m th row which is the last row, corresponding to the selection of the scan line Ls.

In the gradation display operation, the data driver circuit 40 generates, in response to a control signal transmitted from the control unit 50, display voltage Vd based on the display data for the gradation display, to be a gradation display voltage for every data lines Ld. The data driver circuit 40, in response to the control signal transmitted from the control unit 50, simultaneously applies the corresponding display voltages Vd used for the gradation display to n data lines Ld.

In the black display operation, the data driver circuit 40 generates, in response to a control signal transmitted from control unit 50, a display voltage Vd based on the display data for the black display, to be a non-gradation display voltage for every data lines Ld. The data driver circuit 40, in response to a control signal transmitted from the control unit 50, simultaneously applies the corresponding display voltages Vd used for the black display to n data lines Ld.

In the threshold detecting operation, the data driver circuit 40 applies the common detection-use voltage Vm, in response to a control signal transmitted from the control unit 50, simultaneously to n data lines Ld. The data driver circuit 40 outputs, in response to a control signal transmitted from the control unit 50, a detection result corresponding to the respective voltages of n data lines Ld to the control unit 50, sequentially from the first data line Ld.

Configuration of Control Unit 50

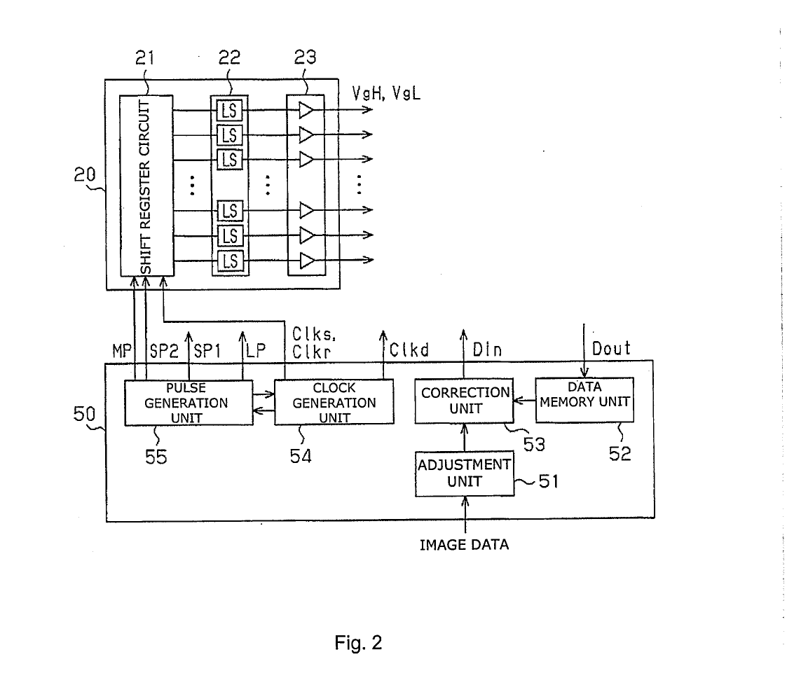

With reference to FIG. 2, a configuration of the control unit 50 is described. As shown in FIG. 2, an adjustment unit 51 interprets image data received by the adjustment unit 51 to be gradation data corresponding to every pixel Px. The adjustment unit 51 performs various adjustments such as gamma correction, luminance control and chromaticity adjustment to the gradation data corresponding to every pixel Px, by using a look up table used for performing various adjustments to the gradation data of every pixel Px and image data received by the adjustment unit 51.

A data memory unit 52 includes a memory region having m rows and n columns corresponding to each of a plurality of (m row×n column) pixels PX. The data memory unit 52 receives detection data Dout which is data concerning the threshold voltage Vth of every pixel Px from the driver circuit 40. The data memory unit 52 stores the detection data Dout for every pixel Px received by the data memory unit 52 into a memory region corresponding to the pixel data Px. The data memory unit 52 updates the detection data Dout corresponding to the pixel Px every time the detection data Dout for every pixel Px is received.

The correction unit 53 reads the detection data Dout for every pixel Px which is stored in the data memory unit 52 and the gradation data corresponding to every pixel Px which is transmitted from the adjustment unit 51. The correction unit 53 performs addition-subtraction on the gradation data for every pixel Px based on the detection data Dout for every pixel Px and outputs display data Din for every pixel Px.

A clock generation unit 54 generates a data shift clock signal Clkd, a display shift clock signal Clks and a detection shift clock signal Clkr. The clock generation unit 54 outputs the data shift clock signal Clkd to the data driver circuit 40 and outputs the display shift clock signal Clks and the detection shift clock signal Clkr to the select driver circuit 20 at mutually different timings.

The data shift clock signal Clkd determines a timing at which the display data Din for every pixel Px is transmitted to the data driver circuit 40 from the correction unit 53. The data driver circuit 40 receives, at every rising of the data shift clock signal Clkd, the display data Din for every pixel Px in the order of display data Din corresponding to the first column pixel Px, display data Din corresponding to second column pixel Px, and display data Din corresponding to n th column pixel. The data driver circuit 40 makes, at a clock period of the data shift clock signal Clkd, the display data Din for every pixel Px correspond with the data line Ld to which the pixel Px is connected.

The display shift clock signal Clks determines a period for switching a candidate of the selected object in the gradation display operation. Also, the display shift clock signal Clks determines a period for switching a candidate of the selected object in the black display operation as well. The select driver circuit 20 selects, at every rising of the display shift clock signal Clks, the scan lines Ls one by one in the order of the first row scan line Ls, the second row scan line Ls, and m row scan line Ls. The clock period of the display clock which is a clock period of the display shift clock signal Clks is much longer than a clock period of the data shift clock signal Clkd. For example, the clock period of the display clock is n times the clock period of the data shift clock signal Clkd.

The detection shift clock signal Clkr determines a period for switching a candidate of the selected object (detecting object), in the threshold detecting operation. The select driver circuit 20 switches, at every rising of the detection shift clock signal Clkr, a candidate to which the selection voltage VgH is applied, one by one in the order of the first row scan line Ls, the second row scan line Ls, and m th row scan line Ls. The period of the detection clock which is a clock period of the detection shift clock signal Clkm is much shorter than a display period.

For example, the period of the detection clock is the same as the clock period of the data shift clock signal Clkd. The select driver circuit 20 scans the candidate to which the selection voltage VgH is applied with the period of the display clock in the gradation display operation. Similarly, in the black display operation, the select driver circuit 20 scans the candidate to which the selection voltage VgH is applied with the period of the display clock. Meanwhile, in the threshold detecting operation, the candidate to which the selection voltage VgH is applied is scanned with a period of the detection clock which is shorter than the period of the display clock.

The detection shift clock signal Clkr includes a section where a high level and a low level repeatedly appear and a shift-standby section where a low level is kept for a threshold detecting period. The timing of an output of the shift-standby section is shifted every time the detection shift clock signal Clkr is outputted, i.e., every time the threshold detecting operation is performed.

For example, according to the present threshold detecting operation, in the detection shift clock signal Clkr, high level and low level repeatedly appear q times at the clock period (1≦q≦m) and subsequently, the shift-standby section is outputted. Meanwhile, according to the next threshold detecting operation, in the detection shift clock signal Clkr, high level and low level repeatedly appear (q+1) times (1≦q≦m) and subsequently, the shift-standby section is outputted. Therefore, in the present threshold detecting operation, scan lines from the first scan line Ls to the q th scan line Ls as candidates of the selected object are sequentially switched, at the period of the detection clock. Then, after the threshold detecting period has elapsed, scan lines from the q+1 th scan line Ls to the m th scan line Ls as candidates of the selected object are sequentially switched again, at the period of the detection clock. In the next threshold detecting operation, scan lines from the first scan line Ls to the q+1 scan line Ls as candidates of the selected object are switched, at the period of the detection clock. Then, after the threshold detecting period elapsed, scan lines from the q+2 th scan line Is to the m th scan line Ls as candidates of the selected object are switched, at the period of the detection clock.

A pulse generation unit 55 generates a start pulse signal SP1, a latch pulse signal LP, a start pulse signal SP2 and a mask pulse signal MP. The pulse generation unit 55 outputs the start pulse signal SP1 and the latch pulse signal LP to the data driver circuit 40. Also, the pulse generation circuit 55 outputs the start pulse signal SP2 to the select driver circuit 20 and the clock generation unit 54 and outputs the mask pulse signal MP to the select driver circuit 20 and the clock generation circuit 54.

The start pulse signal SP1 is a control signal that controls a timing at which display data Din for one row is transmitted to the data driver circuit 40 from the correction unit 53. The data driver circuit 40 receives display data Din corresponding to the pixels Px of every one row, including data from the display data Din corresponding to the pixel Px of the first column to the display data Din corresponding to the pixel Px of the n th column, every time the start pulse signal SP1 is received.

The latch pulse signal LP is a control signal that controls a timing at which the display data Din for one row is held by the data driver 40. The data driver 40 holds the display data Din for one row, including data from the display data Din corresponding to the first column Px to the display data Din corresponding to the n th pixel Px, every time the latch pulse LP is received.

The start pulse signal SP2 is a control signal that controls a timing at which switching of candidates of the selected object is started. The select driver circuit 20 sequentially switches, every time the start pulse signal SP2 is received, the scan lines Ls from the first row scan line Ls to the m th row scan line Ls as candidates of the selected object.

The start pulse signal SP2 is a control signal that controls a timing at which a system clock used for switching the candidate of the selected object is switched between a period of the display clock and a period of the detection clock. The clock generation unit 54 switches, every time the start pulse signal SP2 is received for the number of switching to be switched, a shift clock signal used for switching the selection object from a period of display clock to a period of detection clock.

According to the present embodiment, the number of switching to be switched is set to be three. The clock generation unit 54 changes, every time the start pulse signal SP2 has been received three times, the shift clock signal to have the same period as the detection clock from having the same period as the display clock. Thus, in the gradation display operation, m scan lines Ls as candidates of the selected object are sequentially switched, at a period of the display clock. In the black display operation, first, m scan lines Ls as candidates of the selected object are sequentially switched, at a period of the display clock. Subsequently, in the threshold detecting operation, m scan lines Ls as candidates of the selected object are sequentially switched, at a period of the detection clock.

The mask pulse signal MP is a control signal that controls the output of the shift signal generated by the select driver circuit 20. When the mask pulse signal MP is high level, in the select driver circuit 20, based on the shift signal generated by the select driver circuit 20, the selection voltage VgH is applied to any of the scan lines Ls. Meanwhile, when the mask pulse signal MP is low level, in the select driver circuit 20, regardless of the shift signal generated by the select driver circuit 20, the non-selection voltage VgL is applied to all of the scan lines Ls.

The mask pulse signal MO is usually set to be high level and is switched to low level from the high level every time the start pulse signal SP2 is outputted for the number of switching to be switched. The mask pulse signal MO includes a mask released section where high level is kept for the threshold detecting period. The timing at the mask released section being outputted is synchronized to the above-described shift-standby section and is shifted at every threshold detecting operation.

For example, in the present threshold detecting operation, the detection shift clock signal Clkr repeatedly changes its state between high level and low level q times (1≦q≦m) and subsequently, the mask released section is outputted. Meanwhile, in the next threshold detecting operation, the detection shift clock signal Clkr repeatedly changes its state between high level and low level (q+1) times (1≦q≦m) and subsequently, the mask released section is outputted. Thus, in the present threshold detecting operation, first, scan lines from the first scan line Ls to the q th scan lines Ls as candidates of the selected object are sequentially switched at a period of the detection clock. Then, in this period, applying of selection voltage VgH to the scan line Ls is inhibited. Then, during a threshold detecting period where switching of the candidates of the selected object is stopped, the selection voltage VgH is applied to q th row scan line Ls which is the present candidate. Meanwhile, in the next threshold detecting period, first, scan lines from the first scan line Ls to the (q+1) th scan lines Ls as candidates of the selected object are scanned by a period of the detection clock. In this period, applying the selection voltage VgH to the scan line Ls is inhibited. Then, during a threshold detecting period where switching of the candidates of the selected object is stopped, the selection voltage VgH is applied to (q+1) th row scan line Ls which is the present candidate.

Configuration of Select Driver Circuit 20

With reference to FIG. 2, a configuration fot eh select driver circuit 20 is described.

As shown in FIG. 2, the shift register circuit 21 receives the start pulse signal SP2, the display shift clock Clks and the detection shift clock signal Clkr from the control unit 50. The shift register circuit 21 generates, as a shift signal, m bits of parallel signal including one selected object bit every time the start pulse signal SP2 is received. The shift register circuit 21 sequentially shifts the one selected object bit in the shift signal for every one row from the first row to the m row, every time the display shift clock signal Clks is received. Likewise, the shift register circuit 21 sequentially shifts the one selected object bit in the shift signal for every one row from the first row to the m row, every time the detection shift clock signal Clkr is received.

The shift register circuit 21 outputs a shift signal generated by the shift register circuit 21 when the mask pulse signal MP received by the shift register circuit 21 is high level. Meanwhile, the shift register circuit 21 outputs a shift signal not including the selected object bit, regardless of the shift signal generated by the shift register circuit 21, when the mask pulse signal MP received by the shift register circuit 21 is low level. Then, when the shift clock signal is the display shift clock signal Clks, the shift register circuit 21 outputs a shift signal including the selected object bit, based on high level mask pulse signal MP. Meanwhile, when the shift clock is the detection shift clock signal Clkr, the shift register circuit 21 outputs, during a period excluding the threshold detecting period, a shift signal not including the selected object bit based on low level mask pulse signal MP. These output control of the shift signal is achieved by, for example, disposing m logical AND circuits which corresponds to respective bits of the shift signal at the output end of the shift register circuit 21 and having each of the m logical AND circuits receive the mask pulse signal MP.

A level shifter circuit 22 is a voltage adjusting circuit for a low voltage breakdown circuit to be a high voltage breakdown voltage circuit, in which a shift signal is received from the shift register circuit 21 so as to adjust the voltage of the shift signal to be a drive level of a buffer circuit 23. The buffer circuit 23 receives the shift signal of which voltage is adjusted from the level shifter circuit 22 and adjusts the voltage of the shift signal to be a drive level of the pixel.

Configuration of the Data Driver Circuit 40

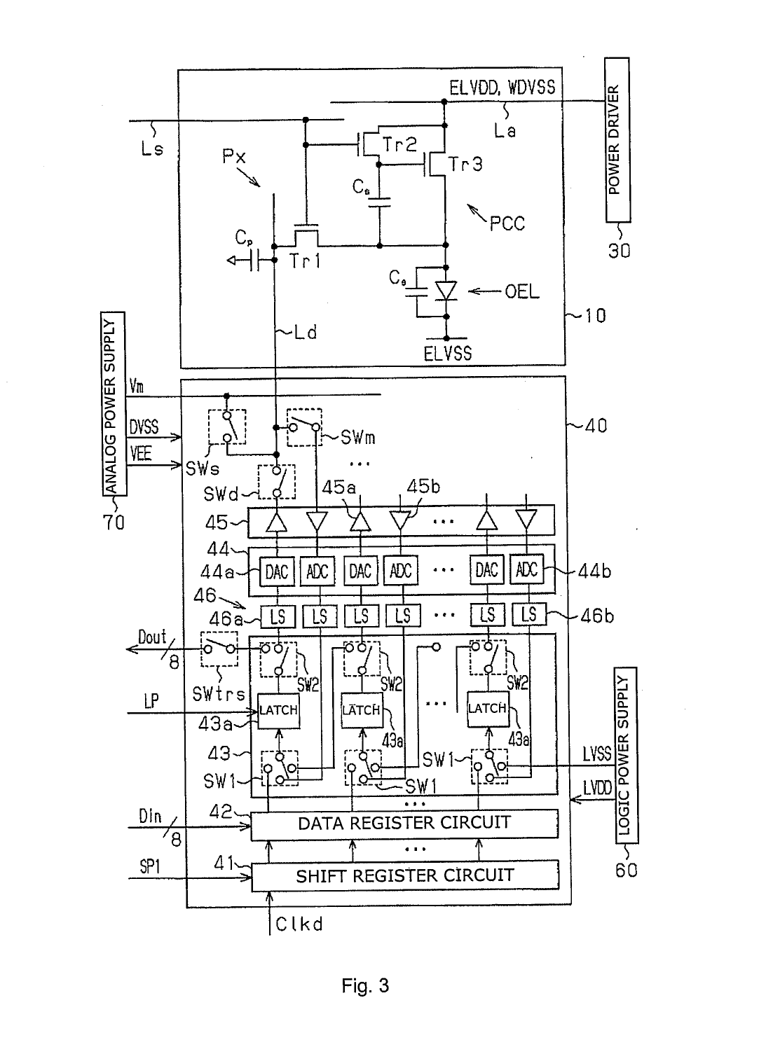

With reference to FIG. 3, the configuration of the data driver circuit 40 is described. As shown in FIG. 3, a shift register circuit 41, a data register circuit 42 and a data latch circuit 43 are configured as a low voltage breakdown voltage circuit and a logic power supply 60 supplies high level logic power supply voltage LVDD and low level logic reference voltage LVSS to these circuits. A DAC/ADC circuit 44 and a buffer circuit 45 are configured as a high voltage breakdown circuit and an analog power supply 70 supplies high level analog power supply voltage DVSS and low level analog reference voltage VEE to these circuits. The analog power supply voltage DVSS is set to be electric potential identical to a write voltage WDVSS and a reference voltage ELVSS.

The shift register circuit 41 receives the start pulse signal SP1 and the data shift clock signal Clkd from the control unit 50. The shift register circuit 41 outputs a shift signal as an n-bit parallel signal including one selected object bit, every time the start pulse signal SP1 is received. The shift register circuit 41 shifts the one selected object bit sequentially in the shift signal and outputs thereof, every time the data shift clock signal Clkd is received.

The data register circuit 42 includes n registers that correspond to respective bits of the shift signal, and one register receives, for example, 8 bits of gradation data from the control unit 50. The data register circuit 42 receives gradation data to be transmitted to one register selected by one selected object bit. In the data register circuit 42, by shifting one selected object bit, all registers are selected and the display data for one row is received from the control unit 50.

The data latch circuit 43 includes n data latches 43a that correspond to respective registers of the data register circuit 42 and receives a latch pulse signal LP which is common to the respective n data latches 43a from the control unit 50.

The respective input ends of n data latches 43a are connected to corresponding registers in the data register circuit 42, in the gradation display operation and the black display operation. The respective n data latches 43a hold gradation data stored in the corresponding registers and the holding is synchronized to the latch pulse signal LP. The respective n-number of data latches 43a output gradation data being held in the data latch 43a to the DAC/ADC circuit 44. Thus, the data latch circuit 43 holds the display data Din for one row acquired by the data register circuit 42 at every input of the latch pulse signal LP and outputs the display data Din held for one row to the DAC/ADC circuit 44.

In the threshold detecting operation, the respective input ends of n data latches 43a are connected to corresponding detection ADC 44b in the display DAC/ADC 44. The respective n data latches 43a hold data outputted by corresponding detection ADC 44b as detection data Dout and the holding is synchronized to the latch pulse signal LP.

The input end of the data latch 43a of the p th column (1≦q≦n) is connected to the output end of the data latch 43a of the (p+1) th column in the threshold detecting operation. The respective data latches 43a of the p th column hold data stored in the data latch of the (p+1) th column as detection data Dout, and the holding is synchronized to the latch pulse signal LP.

The output end of the data latch 43a of the first column is connected to the control unit 50 in the threshold detecting operation and the detection data Dout stored in the data latch 43a of the first column is outputted to the control unit 50. Hence, the data latch 43a of the first column sequentially holds all data stored in the data latch 43a of the (p+1) th column from the data latch 43a of the second column and sequentially outputs the held data to the control unit 50.

The data latch circuit 43 includes n-number of data latches 43a, n input switch SW1 connected to the respective input ends of the n data latches 43a and n output switches SW2 connected to the respective output ends of the n data latches 43a. Also, the data latch circuit 43 includes a transfer switch SWtrs connected between the output switch SW2 of the first column and the control unit 50.

The input switch SW1 is driven in accordance with the control signal transmitted from the control unit 50 and connects the input end of the data latch 43a of the p th column to any one of a p th-column register in the data register circuit 42 or a detection ADC44b of the p th column or the output end of data latch 43a of the (p+1) th column.

When the input end of the data latch 43a and the data register circuit 42 are connected, the data latch 43a holds display data Din stored in the data register circuit 42 at a timing synchronized to the latch pulse signal LP.

When the input end of the data latch 43a and the detection ADC 44b are connected, the data latch 43a holds the data outputted from the detection ADC 44b as detection data Dout at a timing synchronized to the latch pulse signal LP.

When the input end of the data latch 43a of p th column and the output end of the data latch 43a of the (p+1) th column, the data latch 43a of the p th column holds the detection data Dout stored in the data latch 43a of the (p+1) th column at a timing synchronized to the latch pulse signal LP. It is noted that the data latch of the n th column which is the last column is connected to the logic power supply 60 and the logic reference voltage LVSS is applied to the data latch 43a of the n th column.

The output switch SW2 is driven in accordance with the control signal transmitted from the control unit 50 and connects the output end of the data latch 43a of the (p+1) th column to either the display ADC 44a of the DAC/ADC circuit 44 or the input end of the data latch 43a of the p th column.

When the output end of the data latch 43a and the display DAC 44a of the DAC/ADC circuit 44 are connected, the display data Din stored in the data latch 43a is received by the display DAC 44a at a timing synchronized to the latch pulse signal LP.

When the output end of the data latch 43a of the (p+1) th column and the input end of the data latch 43a of the p th column are connected, the detection data Dout stored in the data latch 43a of the (p+1) th column is held in the data latch 43a of the first column at a timing synchronized to the latch pulse signal LP.

The transfer switch SWtrs is driven in accordance with the control signal transmitted from the control unit 50 and switches connection/disconnection between the data latch 43a of the first column and the control unit 50. When the data latch 43a of the first column and the control unit 50 are connected, the detection data Dout stored in the data latch 43a is outputted to the control unit 50.

The DAC/ADC circuit 44 includes n display DACs 44a which are linear digital to analog voltage conversion circuits and n detection ADCs 44b which are analog to digital conversion circuits. Each of the n display DACs 44a converts the display data Din stored in the data latch 43a which is connected to the display DAC 44a to an analog signal voltage and outputs the analog signal voltage to a buffer circuit 45 connected to the display DAC 44a. Each of the n detection ADCs 44b converts the analog signal voltage outputted from the buffer circuit 45 connected to the detection ADC 44b, for example, to 8 bits detection data Dout and outputs the detection data Dout to the data latch 43a connected to the ADC 44b.

In the display DAC44a, the input-output characteristics of the analog signal voltage outputted from the input digital data are linear. The analog signal voltage to be converted is set within a range from the analog power supply voltage DVDD to the analog reference voltage VEE which are applied by the analog power supply 70. Also, in the detection ADC 44b, the input-output characteristics of the digital data outputted from the input analog signal voltage are linear. In the display DAC 44a and the detection ADC 44b, the bit length of the digital data when voltage conversion is applied is set to be an identical value, for example 8 bits.

A level shifter 46a serving as a voltage adjustment circuit that adjusts a voltage of a low voltage breakdown circuit to a voltage of a high voltage breakdown circuit, is disposed between the output switch SW2 and the display DAC 44a. Also, a level shifter 46b is disposed between the detection ADC 44b and the switch SW1. The level shifter 46b serves as a voltage adjustment circuit that adjusts a voltage of a high voltage breakdown circuit to a voltage of a low voltage breakdown circuit.

The buffer circuit 45 includes, for every data line Ld, a buffer circuit 45a that applies display voltage Vd to the data line Ld, a buffer circuit 45b that acquires voltage of the data line Ld and a display switch Swd that switches connection and disconnection between the data line Id and the buffer 45a. Further, the buffer circuit 45 includes, for every data line Ld, a detection switch SWm that switches connection and disconnection between the data line Ld and the buffer 45b and, a detection voltage switch Sws that switches connection and disconnection between the data line Ld and the analog power supply 70.

The buffer 45a amplifies the analog signal voltage transmitted from the display DAC 44a to be a drive level of the pixel circuit so as to generate the display voltage Vd. The display switch Swd is driven in accordance with the control signal transmitted from the control unit 50 and connects the buffer 45a and the data line Ld so as to apply the display voltage Vd to the data line Ld from the buffer 45.

The buffer 45b acquires voltage of the data line Ld and amplifies the acquired voltage to be the drive level of the detection ADC 44b and then outputs the amplified voltage to the detection ADC 44b. The detection switch SWm is driven in accordance with the control signal transmitted from the control unit 50 and connects the buffer 45b and the data line Ld, thereby transmitting the voltage of the data line Ld to the buffer 45b.

The detection voltage switch SWs controls an application of the detection-use voltage Vm to the data line Ld from the analog power supply 70.

Configuration of Pixel Circuit PCC

With reference to FIG. 3, a configuration of the pixel circuit PCC is described.

As shown in FIG. 3, the pixel PX includes an organic EL element OEL and a pixel circuit PCC that makes the organic EL element emit light. The pixel circuit PCC is provided with three transistors Tr1 to Tr3 which are thin film transistors and a storage capacitance Cs. The transistors Tr1 to Tr3 may be amorphous thin film transistors or poly-silicon thin film transistors. According to the present embodiment, the transistors Tr1 to Tr3 are n-channel amorphous thin film transistors.

In the sampling transistor Tr1, the source terminal is connected to the data line Ld and the drain terminal is connected to the anode of the organic EL element OEL and the gate terminal is connected to the scan line Ls. The sampling transistor Tr1 becomes in a conductive state when high level selection voltage VgH is applied to the scan line Ls and becomes in a non-conductive state when low level non-selection voltage VgL is applied to the scan line Ls.

In the switching transistor Tr2, the source terminal is connected to the gate terminal of the current control transistor Tr3, the drain terminal is connected to the power line La and the gate terminal is connected to the gate terminal of the sampling transistor Tr1. The switching transistor Tr2 enters a conductive state when a high level selection voltage VgH is applied to the scan line Ls and a non-conductive state when a low level non-selection voltage VgL is applied to the scan line Ls.

In the current control transistor Tr3, the source terminal is connected to the anode of the organic EL element OEL, the drain terminal is connected to the drain terminal of the switching transistor Tr2 and the gate terminal is connected to the source terminal of the switching transistor Tr2. According to the present embodiment, the threshold voltage Vth of the drain current at the current control transistor Tr3 is a detecting object in the threshold detecting operation.

The holding capacitor Cs is connected between the gate terminal and the source terminal of the current control transistor Tr3. The holding capacitor Cs may be a parasitic capacitance formed between the gate terminal and the source terminal of the current control transistor Tr3 and a further additional capacitive element may be connected in parallel to the parasitic capacitance.

At the cathode terminal of the organic EL element OEL, the reference voltage ELVSS is applied. The reference voltage ELVSS has an electric potential higher than the analog reference voltage VEE, for example, ground potential. In the pixel Px, the organic EL element includes the pixel capacitance Ce and the data line Ld includes parasitic capacitance Cp.

In the display operation, when the write voltage WDVSS is applied to the q th power line La and high level selection signal (selection voltage VgH) is supplied to the q th row scan line Ls, q th row sampling transistor Tr1 and q th row switching transistor Tr2 become in a conduction state. While the q th row sampling transistor Tr1 and the q th row switching transistor Tr2 are in the conduction state, the current control transistor Tr3 in q th row operates in the saturated region. Under this condition, when the display voltage Vd is applied to each of the n data lines Ld, depending on the difference between the write voltage WDVSS and the display voltage Vd, the gate-source voltage Vgs of respective q th row current control transistors Tr3 is held at the holding capacitor Cs as a write voltage.

After the write voltage is held in the holding capacitor Cs in q th row, when the non-selection voltage VgL is applied to q th row scan line Ls, q th row sampling transistor Tr1 and q th row switching transistor Tr2 become in a non-conductive state. When the q th row sampling transistor Tr1 and the q th row switching transistor Tr2 are in the non-conductive state and if drive voltage ELVDD is applied to the q th row power line La, the q th row current control transistor Tr3 allows the drain current to flow through the organic EL element based on the gate-source voltage Vgs. At this time, the drain current at the q th row current control transistor Tr3 varies in the saturation region based on a difference between the gate-source voltage Vgs and the threshold voltage Vth of the current control transistor Tr3. That is, the drain current based on a difference between the write voltage held in the storage capacitance Cs and the threshold voltage Vth of the current control transistor Tr3 flows through the organic EL element OEL.

Then, when the display voltage Vd based on the display data of the gradation display operation is applied to the data line Ld, the drain current corresponding to the display voltage Vd flows through the organic EL element OEL so that the organic EL element OEL is set to the gradation display state. Also, when the display voltage Vd based on the display data, corresponding to the black display operation is applied to the data line Ld, current flowing of the drain current is avoided by the organic EL element OEL so that the organic EL element is set to a non-gradation operation state, i.e., a black display state. The threshold voltage Vth of the current control transistor Tr3 shows a gate-source voltage Vgs of the current control transistor Tr3 when the drain current of the current control transistor Tr3 starts to flow.

Effects of Display Device

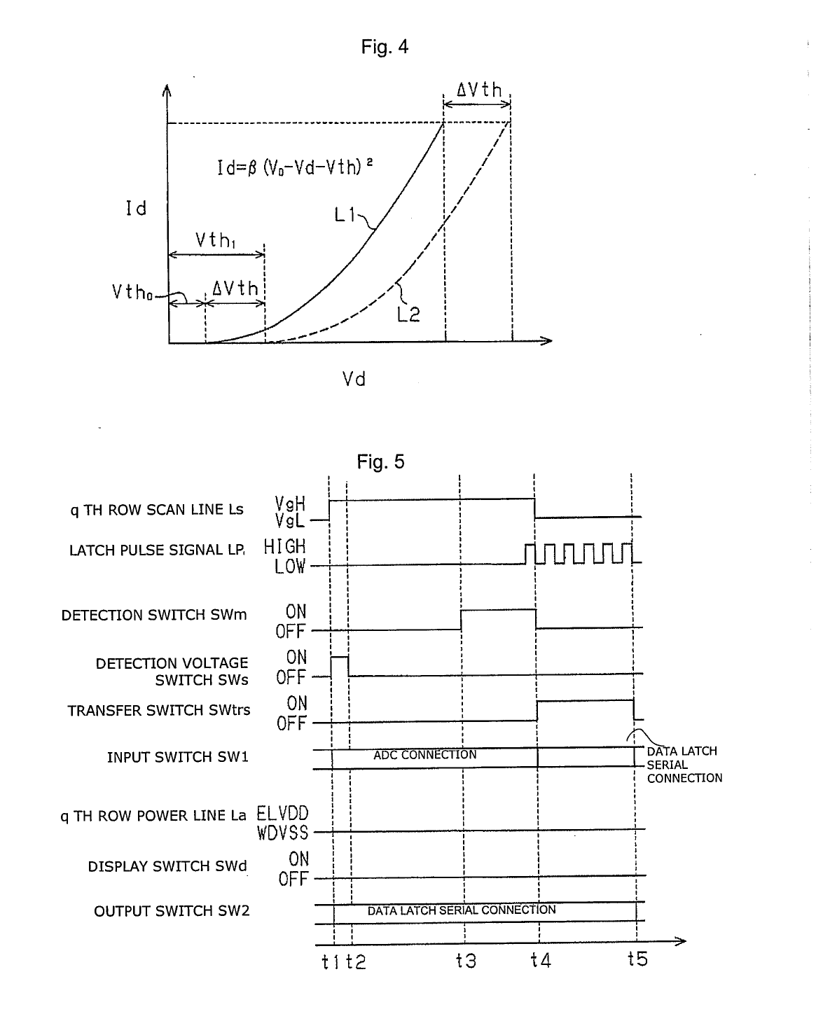

With reference to FIGS. 4 to 7, the threshold detecting operation and the display operation are described. First, with reference to FIG. 4, a dependency between the display voltage Vd and the drain current of the current control transistor is described. In FIG. 4, two cases are exemplified in which mutually different two threshold voltages Vth are applied.

The curved line L1 as shown in FIG. 4 with a solid line illustrates a dependency of the display voltage Vd on the drain current id of the current control transistor Tr3, where the threshold voltage Vth of the current control transistor Tr3 and the current amplification factor 13 of the pixel circuit PCC are the initial value. When assuming the initial value of the threshold voltage Vth is Vth₀, the drain current Id flowing through the pixel circuit PCC is represented as the following equation (1). It is noted that V₀ is the write voltage WDVSS.

Id=β(V₀−Vd−Vₜₕ₀)² (1)

The curved line L2 as shown in FIG. 4 with a dotted line illustrates a dependency of the display voltage Vd on the drain current Id of the current control transistor Tr3, where the drain current Id of the current control transistor Tr3 changes from the initial state due to aging. When assuming the threshold voltage Vth is Vth₁(=Vth₀+ΔVth), the drain current Id flowing through the pixel circuit PCC is represented as a following equation (2).

Id=β(V₀−Vd−Vₜₕ₁)² (2)

As shown in FIG. 4 and the above equations (1) and (2), the curved line L2 shows a shape in which the curved line L1 is shifted parallel for an amount of shift ΔVth. The shape of the curved line L1 and the shape of the curved line L2 are substantially the same before or after the threshold voltage Vth varies. This suggests that a variation in the current amplification factor β can be neglected compared to a variation in the threshold voltage Vth and the display voltage Vd is corrected by using an amount of shift at the current control transistor Tr3, whereby the drain current Id of the current control transistor Tr3 is corrected. According to the present embodiment, the threshold voltage Vth of the current control transistor Tr3 is detected in the threshold voltage Vth detecting operation and corrects the display voltage Vd which is applied to the pixel circuit PCC via the data line

Ld.

Threshold detecting operation With reference to FIG. 5, a change in the drive state of the respective driver circuits 20, 30 and 40 in the above-described threshold detecting period of the threshold detecting operation is described. In the threshold detecting operation, a voltage holding operation, a voltage saturation operation, voltage measuring operation and voltage output operations are performed in this order. FIG. 5 is a timing diagram showing a drive state for respective driver circuits 20, 30, 40 when respective pixels PX in the q th row are an object row for detecting threshold voltage Vth.

As shown in lower side of FIG. 5, in a period where the threshold detecting operation is performed for respective q th row pixels PX, the write voltage WDVSS is continuously applied to the q th row power line La. Also, the display switches SWd are kept in the off state and respective pixel circuits PCC in the q th row are disconnected from the shift register circuit 41 in the data driver circuit 40 and the data register circuit 42. Moreover, the output switch SW2 is kept connected to an adjacent other data latch 43a.

First at the timing t1, the input switch SW1 is connected to the detection ADC 44b and the transfer switch SWtrs is kept in the off state. With this condition, the selection voltage VgH is applied to the q th row scan line Ls whereby the respective switching transistors Tr2 in q th row and the respective sampling transistors Tr1 in q th row are set to the conductive state and the respective current control transistor Tr3 in q th row are driven in the saturation region. Also, the detection voltage switch SWs are changed to be in an on state so that the detection-use voltage Vm is applied to the respective data lines Ld simultaneously from the analog power supply 70.

In this case, the detection-use voltage Vm is set such that a voltage larger than an expected threshold voltage Vth is applied between the gate and source of the current control transistor Tr3. Specifically, the detection-use voltage Vm is set such that difference between the write voltage WDVSS and the detection-use voltage Vm becomes larger than an expected threshold voltage Vth between the gate and the source of the current control transistor Tr3. It is noted that the electric potential of the respective data line Ld to which the detection-use voltage Vm is applied is lower than the electric potential of the power line La to which the write voltage WDVSS is applied and lower than the cathode terminal of the organic EL element OEL.

When the detection-use voltage Vm is applied to the respective data line Ld, current of every pixels Px in accordance with the difference between the detection-use voltage Vm and the write voltage WDVSS flows to the analog power supply 70 via the respective current control transistors Tr3 in the q th row and the respective sampling transistors Tr1 in the q th row. Accordingly, the respective storage capacitances Cs in the q th row holds the gate-source voltage Vgs of the current control transistor Tr3 to which the storage capacitance Cs is connected, thereby terminating the voltage holding operation. Since the electric potential of the anode of the organic EL element is lower than or equal to the electric potential of the cathode side, the organic EL element OEL does not emit light.

At the timing t2, the selection voltage VgH has been applied to the q th row scan line Ls and only the detection voltage switch SWs is switched to the off state under a condition that the detection switch SWm is kept to be off. Thus, in the respective data lines Ld, a portion of the data driver 40 side is switched to a high-impedance state with respect to a portion connected to the sampling transistor Tr1.

At this time, the gate-source voltage Vgs of the respective current control transistors Tr3 in the q th row has been held in the respective storage capacitance Cs in the q th row. Therefore, the drain current is kept flowing at the respective current control transistors Tr3 in the q th row such that the electric potential of the source terminal at the respective current control transistor Tr3 in the q th row approaches the electric potential of the drain terminal at the respective current control transistor Tr3 in the q th row. Then, the more advanced a relaxation time t which is a period elapsed from the timing t2, the more the electric charge stored in the respective storage capacitance Cs in the q th row is discharged. Hence, the voltage between both terminals of the respective storage capacitance Cs, i.e., the gate-source voltage Vgs at the respective transistors Tr3 in the q th row decreases to a threshold voltage Vth at which the drain current does not flow. Then, voltage corresponding to the threshold voltage Vth of the respective current control transistors Tr3 in the q th row is held in the respective storage capacitance Cs in the q th row so as to terminate the voltage saturation operation. The detection switch SWm used for applying detection-use voltage Vm to the respective data lines Ld is kept in the off state after the timing t2.

At the timing t3, the selection voltage VgH has been applied to the q th row scan line Ls and only the detection switch SWm is switched to on. Accordingly, the respective data lines Ld and the respective detection ADC44b are connected and the electric potential of the respective data line Ld which was high impedance state is acquired by the respective detection ADC 44b.

In this case, in the respective storage capacitances Cs of the q th row, a voltage corresponding to the threshold voltage Vth of the respective current control transistors Tr 3 of the q th row is held. Therefore, based on the voltage difference between the electric potential acquired by the respective detection ADC 44b and the write voltage WDVSS, the gate-source voltage Vgs at the respective current control transistors Tr3 of the q th row, i.e., threshold voltage Vth of the respective current control transistor TR3 of the q th row, is detected. The detected electrical potential of the respective data lines Ld is converted to detection data Dout which is digital data by the respective detection ADC 44b, and the converted detection data Dout is outputted to the respective data latches 43a via the level shifter 46b. Subsequently, the respective data latches 43a holds outputted detection data Dout. Then, the voltage measuring operation is terminated.

At the timing t4, non-selection voltage VgL is applied to the q th scan line Ls and the respective switching transistors Tr2 of the q th row and the respective sampling transistors Tr1 of the q th row are switched to the non-conductive state. Under this condition, the respective detection switches are switched off and the transfer switch SWtrs is switched on. Further, the input switch SW1 is connected to the adjacent data latch 43a so as to serially connect the respective data latches 43a.

At this time, latch pulse signal LP is outputted to the data driver circuit 40 from the control unit 50 and the detection data Dout held in the respective data latches 43a is sequentially transferred to the control unit 50, synchronized to the timing of the latch pulse signal LP. Thus, data concerning the threshold voltage Vth of the respective n-number of current control transistors Tr3 arranged in the q th row is sequentially transferred to the control unit 50. In FIG. 5, for convenience of explanation, the number of times in which the latch pulse signal LP repeatedly becomes active is omitted.

At timing t5, the non-selection voltage VgL has been applied to the q th row scan line Ls and the transfer switch SWtrs is switched to OFF. Also, the input switch SW1 connects the input end of the data latch 43a to a register of the data register circuit. Hence, the voltage output operation is terminated and the threshold detecting operation for the current control transistor Tr3 arranged in the q th row is terminated.

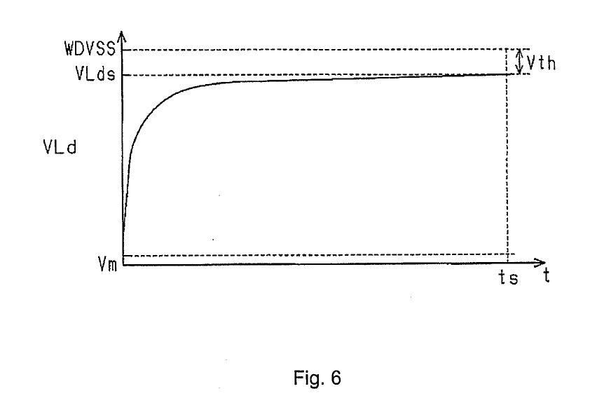

With reference to FIG. 6, a change in data line potential VLd which is an electric potential of the data line Ld during a period from the above-described timing t2 to the above-described timing t3 is described.

As shown in FIG. 6, when the relaxation time t which is an elapsed time from the timing t2 is advanced, the data line potential VLd approaches the write voltage WDVSS from the detection-use voltage Vm, in accordance with a discharge of stored charge in the holding capacitor Cs connected to the data line Ld. Then, when the relaxation time t advances to the saturation time ts, the data line potential VLd is saturated at the saturation voltage VLd so that the drain current does not flow. At this point, a difference between the write voltage WDVSS and the saturation voltage VLds is set as a threshold voltage Vth. The saturation time ts is, for example, 3 nsec to 10 nsec and the period from the timing t2 to the timing t3 is set to be larger than this saturation time ts.

Display Operation

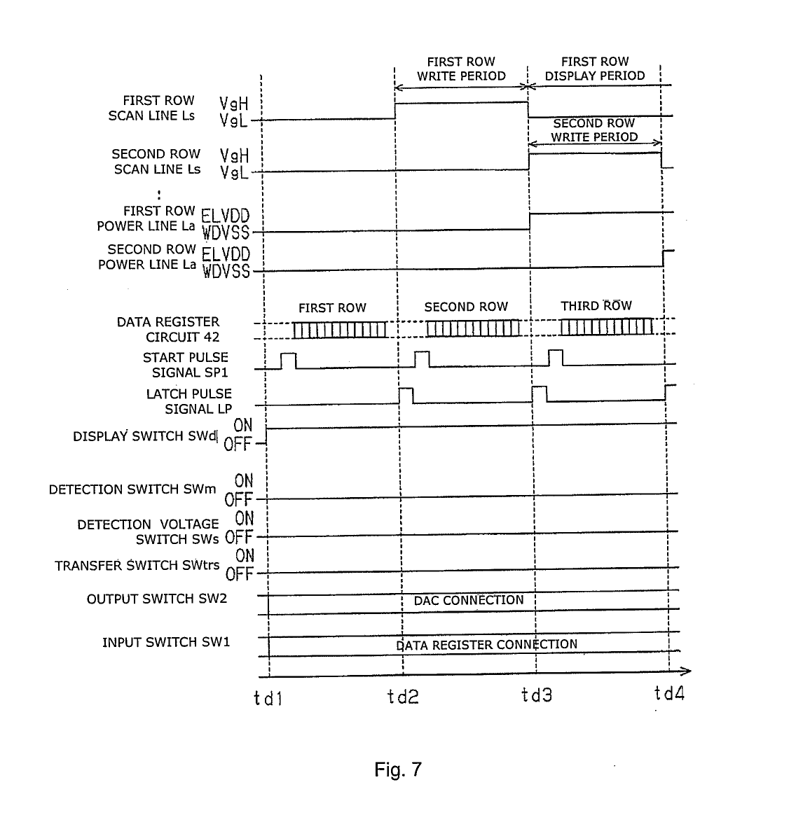

With reference to FIG. 7, a change in the drive state of the respective driver circuit 20, 30, 40 in the gradation display operation is described. In the gradation display operation, a writing operation and emitting operation are performed in this order. A change in the drive state of the drive circuit 20, 30, 40 in the black display operation is the same as the gradation display operation in a period from the start to the timing at the start of the threshold detecting operation.

As shown in the lower side of FIG. 7, in a period where the gradation display operation is performed, the respective detection switch SWm, the respective detection voltage switch SWs and the transfer switch SWtrs are kept in the off state. Also, each of the respective output switches SW2 are kept in a state where the data latch 43a and the display DAC 44a are connected. Each of the respective input switches SW1 is kept in a state where the data latch 43a and the data register circuit 42 are connected.

First, at the timing td1, the shift register circuit 41, the data register circuit 42, the data latch 43a, the display DAC 44a, the buffer 45a and the data line Ld are serially connected by switching the respective display switches SWd to be on. Subsequently, the start pulse signal SP1 is received by the driver circuit 40, whereby the shift signal is transmitted to the data register circuit 42 from the shift register circuit 41. Thus, the display data Din in the first row is acquired by the data register circuit 42 from the control unit 50.

At the timing td2, the selection voltage VgH is applied to the first row scan line Ls and the write voltage WDVSS is applied to the first row power line La so that the respective sampling transistors Tr1 in the first row and the respective switching transistors Tr2 in the first row are set to the conductive state. Further, each of the respective current control transistors Tr3 in the first row becomes a state capable of being driven in a saturated state.

At this point, the latch pulse signal LP is outputted to the data driver circuit 40, whereby the display data Din in the first row is simultaneously stored in the respective data latch 43a. The display data in the first row stored in the n data latches 43a is converted to an analog signal voltage by the n display DACs 44a via the n level shifters 46a and outputted, as a display voltage Vd in the respective columns, to the respective data lines Ld. The gate-source voltage Vgs of the respective current control transistor Tr3 in the first row becomes a value corresponding to a difference between the write voltage WDVSS and the display voltage Vd and is held in the storage capacitance Cs as a write voltage. Thus, the writing operation corresponding to the respective pixels Px in the first row is terminated. The display voltage Vd applied to the respective data lines Ld is a voltage obtained by a calculation in which a difference between the detection data Dout corresponding to the respective pixels Px in the first row and the threshold voltage Vth as a reference are added to or subtracted from the gradation data after an adjustment.

In this case, the start pulse signal SP1 is outputted again to the data driver circuit 40 whereby the shift signal is outputted to the data register circuit 42 from the shift register circuit 41. As a result, the display data Din in the second row is acquired by the data register circuit 42 from the control unit 50.

At the timing td3, non-selection voltage VgL is applied to the first scan line Ls and the drive voltage ELVDD is applied to the first row power line La so that the respective sampling transistors Tr1 in the first row and the respective switching transistors Tr2 in the first row are set to the non-conductive state. Then, each of the respective current control transistors Tr3 in the first row supplies, based on a difference between the write voltage held in the respective storage capacitances Cs in the first row and the threshold voltage Vth at the current control transistor Tr3 to which the storage capacitance Cs is connected, the drain current to corresponding organic EL element OEL. At this point, in the display voltage Vd applied to the respective data lines Ld, an amount corresponding to variation of the threshold voltage Vth is corrected so that an amount corresponding to variation of the threshold voltage Vth is also corrected in the drain current supplied to the organic EL element OEL. Accordingly, emitting operation for the respective pixels Px in the first row is performed.

At this point, the selection voltage VgH is applied to the second row scan line Ls and the write voltage WDVSS is applied to the second row power line La so that the respective sampling transistors Tr1 in the second row and the respective switching transistors Tr2 in the second row are set to the conductive state. Also, the respective current control transistors Tr3 in the second row become in a state capable of being driven in the saturation region. Moreover, the latch pulse signal LP is outputted again to the data driver circuit 40, whereby the display data Din in the second row is held in the respective data latches 43a. The display data Din in the second row which is held in the respective data latches 43a is converted to an analog signal voltage by the respective display DAC44a via the respective level shifter 46a, and then the analog signal voltage is outputted to the respective data lines Ld as a display voltage Vd in the respective columns. The gate-source voltage Vgs of the respective current control transistors Tr3 in the second row becomes a voltage corresponding to a difference between the write voltage WDVSS and the display voltage Vd, being held in the respective storage capacitance Cs in the second row. Then, the writing operation for the respective pixels Px in the second row is terminated.

The writing operation and the emitting operation are performed in this order and these gradation display operation is performed sequentially from the first row to the n th row at the display clock period. Thus, an image as a single frame is displayed. As a display operation, when a black display operation that displays black image is performed, black display data which is image data used to display a black image is used.

Detection Operation Timing

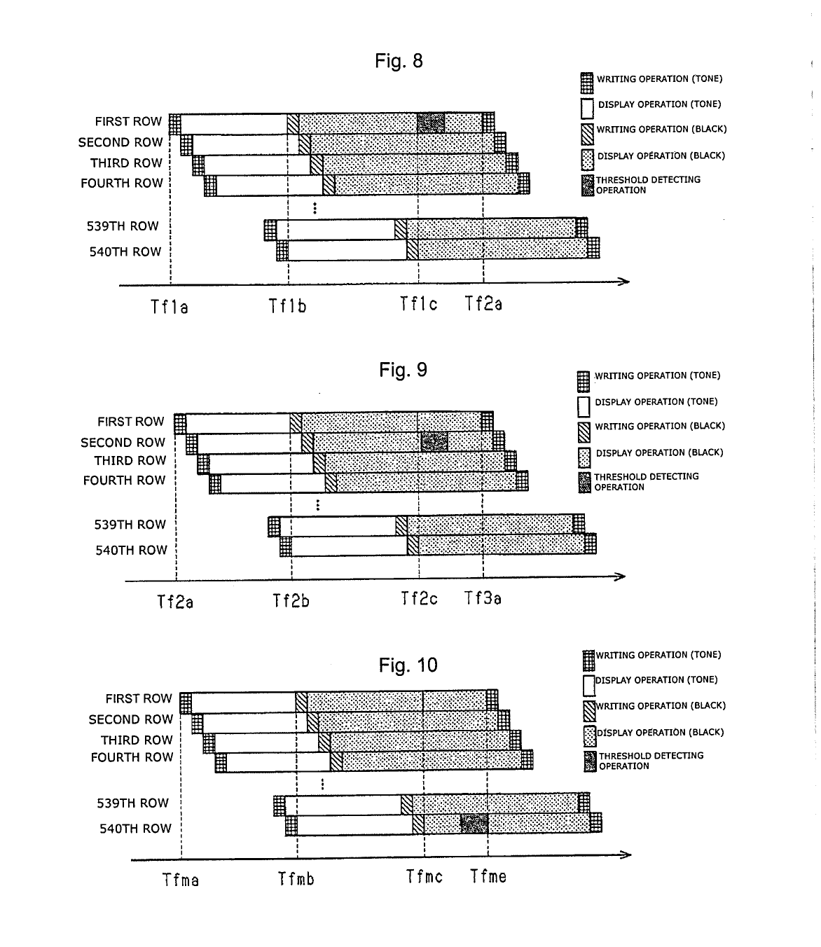

With reference to FIG. 8 to FIG. 10, a timing of the threshold detecting operation performed in the black display operation is described. In the followings, as an example, in a case in which pixels Px are arranged as 540 rows×960 columns and the frame rate is set to be 60 fps is described. FIG. 8 shows a timing of the threshold detecting operation in the black display operation at the first frame. FIG. 9 shows a timing of the threshold detecting operation in the black display operation at the second frame and FIG. 10 shows a timing of the threshold detecting operation in the black display operation at the 540 th frame.

As shown in FIG. 8, first, at a timing Tf1a, the writing operation in the gradation display operation is started at the respective pixels Px in the first row. When the writing operation in the gradation display operation is completed at the respective pixels Px in the first row, an emitting operation in the gradation display operation is started at the respective pixels Px in the first row and the writing operation in the gradation display operation is started at the respective pixels Px in the second row. Thus, the writing operation in the gradation display operation is started sequentially from the first row to the 540 th row at the display clock period and the emitting operation in the gradation display operation is started sequentially from a row where the writing operation in the gradation display operation is completed.

In a timing Tf1b, the writing operation in the gradation display operation is completed for the 540 th row which is the last row and the writing operation in the black display operation is started at the respective pixels Px in the first row. When the writing operation in the black display operation is completed at the respective pixels Px in the first row, a non-emitting operation in the black display operation is started at the respective pixels Px in the first row and the writing operation in the black display operation is started at the respective pixels Px in the second row. Thus, the writing operation in the black display operation is started sequentially from the first row to the 540 th row at the display clock period and the non-emitting operation in the black display operation is started sequentially from a row where the writing operation in the black display operation is completed.

At a timing Tf1c, a start operation of the non-emitting operation in the black display operation is completed for the 540 th row which is the last row and a candidate to which the selection voltage VgH is applied is scanned sequentially from the first row to the 540 th row with the detection clock period. At this point, first, a candidate to which the selection voltage VgH is applied, i.e., a row of the detecting object from which the threshold voltage Vth is detected, is set to be the first row and then, the threshold detecting operation to the respective pixels Px in the first row is performed during the threshold detecting period.

Thus, the detection data Dout concerning the respective current control transistors Tr3 in the first row is stored in the data memory unit 52 of the control unit 50. When the threshold detecting operation for the respective pixels Px in the first row is completed, a bit shift of the selected object bits at the detection clock period is repeatedly performed sequentially from the second row to the 540 th row. Meanwhile, the non-selection voltage VgL is applied to all of the scan lines Ls. As a result, all of the pixels PX wait in a state of black display.

At a timing Tf2a, a bit shift of the selected object bits at the detection clock period advances, in response to an input of the detection shift clock signal Clkr, to the 540 th row which is the last row. Then, the writing operation in the gradation display operation is started again to the respective pixels Px in the first row.

As shown in FIG. 9, at a timing Tf2a, the writing operation in the gradation display operation is again started sequentially from the first row to the 540 th row, and the emitting operation in the gradation display operation is started sequentially from a row where the writing operation in the gradation display operation is completed.

At a timing Tf2b, the writing operation in the gradation display operation is advanced with the display clock period up to the 540 th row which is the last row and the emitting operation in the gradation display operation is started sequentially from a row where the writing operation in the gradation display operation is completed. Next, the writing operation in the black display operation is advanced again sequentially with the display clock period from the first row to the 540 th row at the display clock period, and the non-emitting operation in the black display operation is started sequentially from a row where the writing operation in the black display operation is completed.

At a timing Tf2c, a start operation of the non-emitting operation in the black display operation is completed up to the 540 th row which is the last row and a candidate to which the selection voltage VgH is applied, is scanned sequentially from the first row to the 540 th row with the detection clock period. At this time, the second row is selected for a detecting object row from which the threshold voltage Vth is detected and then, a bit shift of the selection object bit at the detection clock period is advanced to the second row. When the first row is selected for the candidate to which the selection voltage VgH is applied, the non-selection voltage VgL is applied to the scan line Ls. When the second row is selected for the candidate to which the selection voltage VgH, the threshold detecting operation to the respective pixels Px in the second row is performed in the threshold detecting period.

Thus, the detection data Dout concerning the respective current control transistor Tr3 in the second row is stored in the data memory unit 52 of the control unit 50. When the threshold detecting operation of the respective pixels Px in the second row is completed, a bit shift of the selected object bit at the detecting clock period is repeatedly performed sequentially from the third row to the 540 th row. Meanwhile, non-selection voltage VgL is applied to all of the scan lines Ls. As a result, all of the pixels Px wait in a state of the black display.

At a timing Tf3a, a bit shift of the selected object bit with the detection clock period advances to the 540 th row which is the last row by an input of the detection shift clock signal Clkr and the writing operation in the gradation display operation is started again to the respective pixels Px in the first row.

As shown in FIG. 10, at a timing Tfma, the writing operation in the gradation display operation is again started sequentially from the first row to the 540 th row, and the emitting operation in the gradation display operation is started sequentially from a row where the writing operation in the gradation display operation is completed.

At a timing Tfmb, the writing operation in the gradation display operation is advanced with the display clock period up to the 540 th row which is the last row and the emitting operation in the gradation display operation is started sequentially from a row where the writing operation in the gradation display operation is completed. Next, the writing operation in the black display operation is advanced again sequentially with the display clock period from the first row to the 540 th row at the display clock period, and the non-emitting operation in the black display operation is started sequentially from a row where the writing operation in the black display operation is completed.

At a timing Tfmc, a start operation of the non-emitting operation in the black display operation is completed up to the 540 th row which is the last row, and a candidate to which the selection voltage VgH is applied is scanned sequentially from the first row to the 540 th row with the detection clock period. At this time, the 540 th row is selected for a detecting object row from which the threshold voltage Vth is detected. When rows from the first row to 539 th row are selected for the candidate to which the selection voltage VgH is applied, the non-selection voltage VgL is applied to the scan line Ls. When the 540 th row is selected for the candidate to which the selection voltage VgH, the threshold detecting operation to the respective pixels Px in the 540 th row is performed in the threshold detecting period. Thus, the detection data Dout concerning the respective current control transistor Tr3 in the 540 th row is stored in the data memory unit 52 of the control unit 50.

At a timing Tfme, the threshold detecting operation to the respective pixels in the 540 th row is completed and the writing operation in the gradation display operation is started again to the respective pixels Px in the first row.

Thus, in a period where a single frame is displayed, after the non-emitting operation in the black display operation is started up to the 540 th row, the threshold detecting operation is performed for the pixels PX in a specific row. The detecting object row of the threshold voltage Vth is shifted at every one row in each frame sequentially from the pixels PX in the first row along a scanning direction. That is, in the k th frame (k is an integer number, one or higher), when the threshold detecting operation is performed for the pixels Px in the q th row (1≦q≦539), in the k+1 th frame, the threshold detecting operation to the pixels in the q+1 th row. When the detecting object row reaches the last row, the detecting object row returns to the first row.

At this point, the detecting data Dout is stored in a memory region corresponding to the respective pixels Px in the q th row in the data memory unit 52 of the control unit 50 to be updated. Hence, at the k+1 frame, the control unit 50 uses the latest detection data Dout as q th detection data Dout, when the display data Din is generated in the display operation. The control unit 50 uses a previous detection data which was used at the k th frame for the detection data Dout of a row other than q th row. Therefore, the detection data Dout of the respective rows are updated every time the display of the frame is repeated for 540 times.

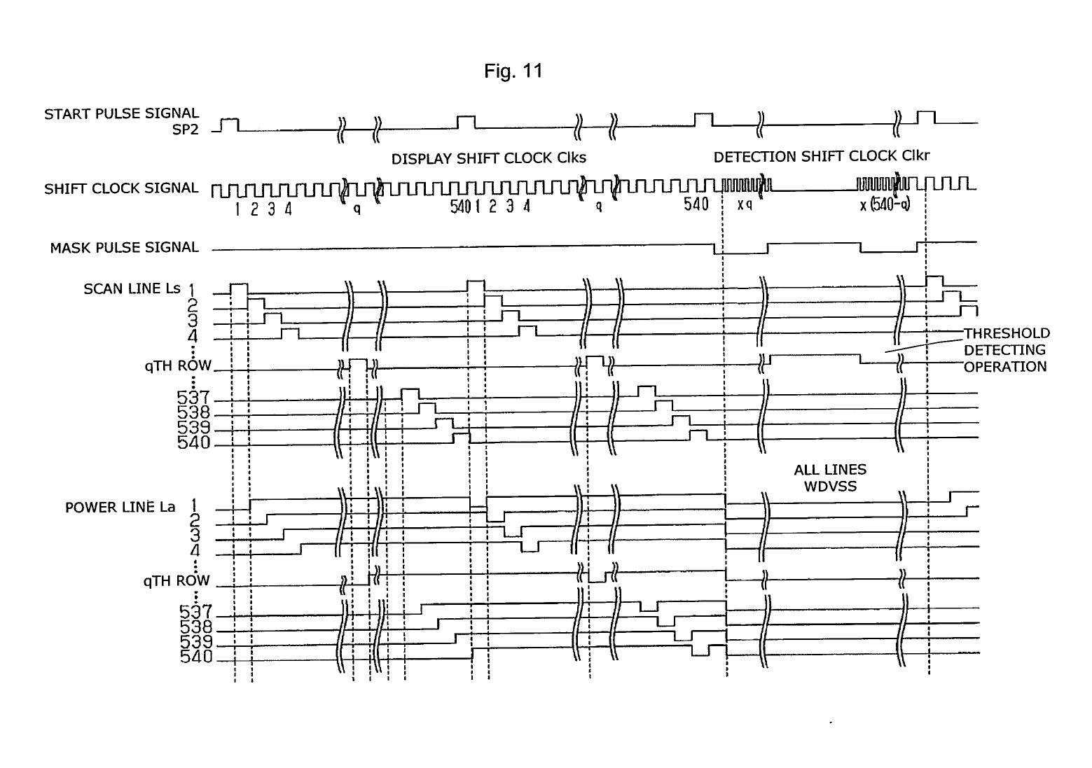

With reference to FIG. 11, a change in the respective control signals in a period for displaying a single frame is described in detail. In the followings, a case is described where the detecting object row in the k th frame corresponds to the respective pixels Px of the q th row.

In the select driver circuit 20, first, a shift signal at the display clock period is generated in response to an input of the start pulse signal SP2 and the selection voltage VgH is applied to the respective scan lines Ls sequentially at a timing based on the shift signal. At this time, the selection voltage VgH is applied sequentially from the first row scan line Ls to the 540 th row scan line Ls at the display clock period. Also, the write voltage WDVSS is applied sequentially from the first row power line La to the 540 th row power line La at the display clock period as well. Then, while the selection voltage VgH is applied to the q th row scan line Ls and the write voltage WDVSS is applied to the q th row power line La, the display voltage Vd based on the display data of the gradation display is applied to the respective pixel circuits PCC of q th column via the respective data lines Ld. Moreover, the non-selection voltage VgL is applied to the scan line Ls in the order of a row in which the selection voltage VgH is applied and the drive voltage ELVDD is applied to the power line La in the order of a row in which the write voltage WDVSS is applied. Then, while the non-selection voltage VgL is applied to the q th scan line LS and the drive voltage ELVDD is applied to q th power line La, in the respective pixel circuits PCC of the q th row, the drain current based on the display data Din of the gradation display is supplied to the organic EL element OEL.

When the writing operation is completed up to the 540 th row which is the last row, in response to an input of the start pulse signal SP2, the selection voltage VgH is applied to the respective scan lines Ls at the display clock period, sequentially from the first row to the 540 th row. Also, the write voltage WDVSS is applied to the respective power lines La at the display clock period, sequentially from the first row power line La to the 540 th row power line La. Then, while the selection voltage VgH is applied to the q th row scan line Ls and the write voltage WDVSS is applied to the q th row power line La, the display voltage Vd based on the display data Din of the black display is applied to the respective pixel circuits PCC of the q th row via the respective data lines Ld. Further, the non-selection voltage VgL is applied to the scan line Ls sequentially from a row to which the selection voltage VgH is applied and the drive voltage ELVDD is applied to the power line La sequentially from a row to which the write voltage WDVSS is applied. Then, while the non-selection voltage VgL is applied to the q th row scan line Ls and the drive voltage ELVDD is applied to the q th row power line La, in the respective pixel circuits PCC, based on the display data Din of the black display, supplying drain current to the organic EL element is stopped.

When the black display operation is started up to the 540 th row which is the last row, the write voltage WDVSS is applied to the respective power line La. Also, the start pulse signal SP2 is the number of switching to be switched and the shift clock signal used for scanning the scan line Ls is switched to the detection clock period from the display clock period. Then, in the shift register circuit 21 of the selection drive circuit 20, a shift signal is generated at the detection clock period and the selected object bits in the shift signal are shifted up to the q−1 row. In this period, the mask pulse signal MP is kept in the low level and the shift signal having no selection object bits is continuously outputted regardless of the generated shift signal.

At a timing where the selected object bit is shifted up to the q th row, the mask pulse signal is switched to high level and the selection voltage VgH is applied to the q th scan line Ls. Then, the threshold voltage Vth is detected from the respective pixels Px in the q th row. When the detection data Dout for the respective pixels Px of the q th row is outputted from the drive circuit 40 and the threshold detecting period is elapsed from when the mask pulse signal MP is switched to high level, the mask signal MP is switched to low level again. In the shift register circuit 21 of the select driver circuit 20, a shift signal is generated at the detection clock period and the selection object bit in the shift signal is shifted up to the 540 th row. In this period, since the mask pulse signal is kept at a low level, in the shift register circuit 21 of the select driver circuit 20, a shift signal having no selection object bit is continuously outputted regardless of the generated shift signal.

When the selection object bit in the shift signal is shifted up to the 540 th row, in response to an input of the start pulse signal SP2, the mask pulse signal MP is switched to high level again. Then, the selection voltage VgH is applied to the respective scan lines Ls at the display clock period from the first row scan line Ls to the 540 th row scan line Ls and the writing operation in the gradation display operation is again started sequentially from the first row pixel Px.

According to the first embodiment, the following effects can be obtained.

(1) The threshold voltage Vth of the current control transistor Tr3 in the pixel circuit PCC is measured. Then, by using the detection data Dout based on the measured threshold voltage Vth, an image data is corrected and the display data Din is generated. The display voltage Vd based on the display data Din is applied to the pixel circuit PCC. Accordingly, even when the threshold voltage Vth of the current control transistor Tr3 varies, the image data is corrected based on the threshold voltage Vth after the variation, so that degradation of the image to be displayed can be avoided.

(2) The threshold detecting operation is performed in a period during which a single frame is displayed. Hence, compared to a case where the threshold detecting operation is performed only when the display device is activated or the operation is resumed from an inactive state, a period for updating the detection data Dout becomes shorter. Therefore, in a case where a variation in the threshold voltage Vth of the current control transistor Tr3 increases in a short period of time, e.g., when a high contrast image needs to be displayed, a degradation of the image can be avoided.

(3) In a single threshold detecting operation, detecting data concerning the threshold voltage Vth is performed for only n-number of pixels connected to one scan line Ls. Therefore, compared to a case where the detection of the data concerning the threshold voltage Vth is performed for all pixels Px or performed once for the pixels Px in a plurality of rows, time required for a single threshold detecting operation becomes shorter. Accordingly, even if the threshold detecting operation is implemented in a period where a single frame is displayed, display performance of the image in the display device can avoid being influenced by the threshold detecting operation.

(4) In particular, since the threshold detecting operation is performed while the black display operation inserted in order to make a display of the moving image clear is performed, a display performance of the image can be effectively avoided from being influenced from the threshold detecting operation.

(5) In the threshold detecting operation, a candidate of the detecting object row is switched sequentially from the first row to the last row. That is, even in the threshold detecting operation, similar to the gradation display operation or the black display operation, a candidate of the selected object is switched. Therefore, the select driver circuit serves as a configuration in which the detecting object row is changed when every frame is displayed.

(6) Further, in the threshold detecting operation, a period for switching the candidate of the detecting object row is a detecting clock period which is shorter than the display clock period. Accordingly, compared to a case where a display clock period is used for a period for switching a candidate of the detecting object row, a period required for the threshold detecting operation is short.

(7) The detecting object row of the threshold voltage Vth is shifted for one row, sequentially from the first row pixel Px to the scanning direction every time a single frame is displayed. Therefore, compared to a configuration in which the detecting object row of the threshold voltage Vth is set with an interval along the scanning direction, the display data Din can be precisely corrected in the scanning direction based on the threshold voltage Vth.

### Second Embodiment

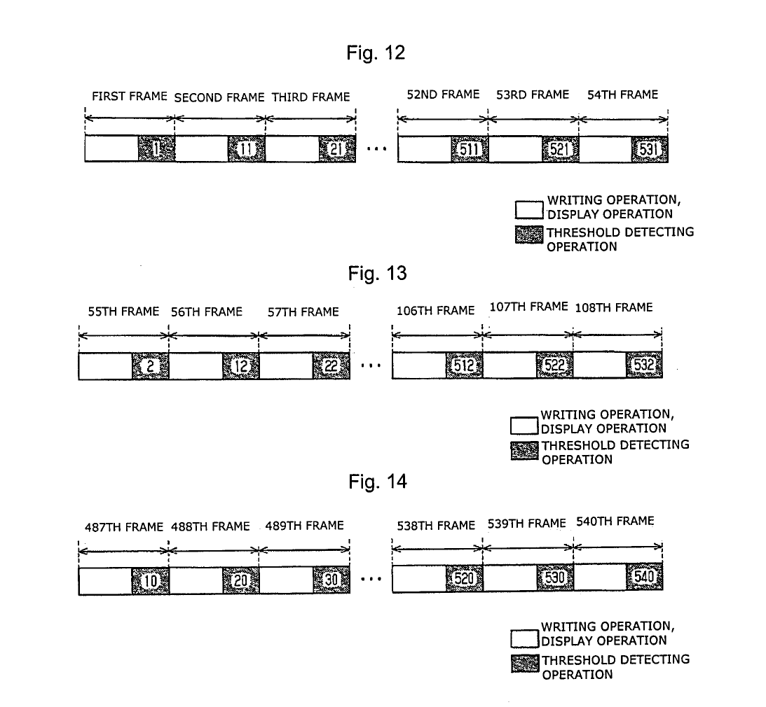

With reference to FIGS. 12 to 14, regarding a display device according to the second embodiment, differences between the display device according to the first embodiment and a display device according to the second embodiment are mainly described. According to the second embodiment, m-row scan lines are divided into a plurality of scan line groups including mutually adjacent 10 rows of scan lines. According to the second embodiment, the threshold detecting object of every frame is set at every scan line group, which is different from that of the first embodiment. Other essential configurations are same as the first embodiment. Hence, elements substantially the same as that of the first embodiment are labelled with identical reference numbers and redundant explanation is omitted.

As shown in FIG. 12, in the first frame, the writing operation in the gradation display operation is started sequentially from the first row, and the emitting operation in the gradation display operation is started sequentially from a row where the writing operation in the gradation display operation is completed. When the writing operation in the gradation display operation is completed up to the last row, the writing operation in the black display operation is started sequentially from the first row. Then, the non-emitting operation in the black display operation is started sequentially from a row where the writing operation in the gradation display operation is completed.

When a start of the non-emitting operation in the black display operation is completed up to the last row, the threshold detecting operation is started. In the threshold detecting operation, the first row as a detecting object row is selected from the first scan line group, and the detection data Dout of the respective pixels Px in the first row is stored in the data memory unit 52 of the control unit 50. During this period, the black display operation for the pixels PX corresponding to all rows has been conducted.

In the second frame, as similar to the first frame, the gradation display operation and the black display operation are performed sequentially from the first row. When a start of the non-emitting operation is completed up to the last row, the threshold detecting operation is started. In the threshold detecting operation in the second frame, 11 th row as a detecting object row is selected from the second scan line group, and the detection data Dout of the respective pixels Px in the 11 th row is stored in the data memory unit 52 of the control unit 50. During this period, the black display operation for the pixels PX corresponding to all rows has been conducted.

Thus, every time a single frame is displayed, the detecting object row is shifted by 10 rows from the first row pixel Px to the 531st row Px. At this point, the detection data Dout for the detecting object row is stored in a memory region corresponding to the detecting object row in the data memory unit 52 of the control unit 50. Then, when the display data Din is generated in the display operation of the next frame, the detection data Dout updated as a detection data Dout of the previous detecting object row is employed.

As shown in FIG. 13, in the 55 th frame, the second row as a detecting object row is selected from the first scan line group and the detection data Dout of the respective pixel data Px in the second row is stored in the data memory unit 52 of the control unit 50. When the threshold detecting operation is completed, a display operation of the 56 th frame is started. In the 56 th frame, the 12 th row as a detecting object row is selected from the second scan line group. The detection data corresponding to the respective pixels Px in the 12 th row is stored in the data memory unit 52 of the control unit 50.

Thus, every time a single frame is displayed, the detecting object row is shifted by 10 rows from the second row pixel Px to the 532nd row Px. At this point, the detection data Dout for the detecting object row is stored in a memory region corresponding to the detecting object row in the data memory unit 52 of the control unit 50. Then, when the display data Din is generated in the display operation of the next frame, the detection data Dout updated as detection data Dout of the previous detecting object row is employed.

As shown in FIG. 14, in the 487 th frame, the 10 th row as a detecting object row is selected from the first scan line group and the detection data Dout of the respective pixel data Px in the 10 th row is stored in the data memory unit 52 of the control unit 50. When the threshold detecting operation is completed, a display operation of the 488 th frame is started. In the 488 th frame, the 20 th row as a detecting object row is selected from the second scan line group. The detection data corresponding to the respective pixels Px in the 20 th row is stored in the data memory unit 52 of the control unit 50.

Thus, every time a single frame is displayed, the detecting object row is shifted by 10 rows from the 10 th row pixel Px to the 540 th row Px. At this point, the detection data Dout for the detecting object row is stored in a memory region corresponding to the detecting object row in the data memory unit 52 of the control unit 50. Then, when the display data Din is generated in the display operation of the next frame, the detection data Dout updated as a detection data Dout of the previous detecting object row is employed. As a result, the detection data Dout of the respective row are updated once every time the frame is displayed for m-times.

According to the second embodiment, the following effects can be obtained other than effects described in the above (1) to (6).

(8) Every time single frame is displayed, the detecting object row is shifted by 10 rows along the scanning direction. When the detecting object row is shifted at every one row, for example, while the frame is repeatedly displayed for 10 times, a range of row in which the threshold voltage Vth is detected is biased to the 10 th row from the first row in the display panel. Meanwhile, the detecting object row is shifted for every 10 rows, for example, while the frame is repeatedly displayed for 10 times, a range including a row in which the threshold voltage Vth is detected, ranges from the first row to the 100 th row in the display panel. Therefore, since the range including the detecting object row is expanded in a short period of time, in case where a variation in the threshold voltage Vth influences in a wide area at the display panel, degradation of the image can be effectively avoided.

### Third Embodiment

Regarding the display device according to the third embodiment, differences between the display device of the third embodiment and that of the second embodiment will mainly be described. According to the third embodiment, the form of storage of the detection data Dout obtained by the threshold detecting operation is different from the second embodiment, however, other basic configurations are the same as that of the second embodiment. Hence, elements substantially the same as that of the second embodiment are labelled with identical reference numbers and the redundant explanations are omitted.

According to the third embodiment, similar to the second embodiment, during a period where a single frame is displayed, after the black display operation is started up to the last row, pixels PX of the specific row are treated as the detecting object row of the threshold voltage Vth. Then, the detecting object row of the threshold voltage Vth are shifted along the scanning direction by 10 rows every time a single frame is displayed.

The data memory unit 52 of the control unit 50 includes a memory region having m/10 rows×n columns. The respective 10 pixels which are included in one scan line group and arranged along the column direction correspond to one memory region. That is, in the data memory unit 52, respective pixels PX arranged along the column direction in the scan line group correspond to one memory region. The data memory unit 52 stores the detection data Dout for every pixel Px received by the data memory unit 52 to the memory region which corresponds to the pixel Px. The data memory unit 52 updates the detection data Dout corresponding to the pixel Px every time the detection data Dout for every pixel Px is received.

For example, the data memory unit 52 makes respective pixels Px in the first column in the first scan line group correspond to a memory region of the first row and the first column, and makes respective pixels Px in the second column in the second scan line group to be corresponded to a memory region of the second row and the second column. Moreover, the data memory unit 52 makes respective pixels Px in the 959 th column in the 54 th scan line group to be corresponded to a memory region of the 54 row and the 959 th column, and makes respective pixels Px in the 960 th column in the 54 th scan line group to be corresponded to a memory region of the 54 th row and the 960 th column.

The data memory unit 52 updates, when the detection data Dout corresponding to the respective pixels Px in the first row is received, the detection data Dout in a memory region of the first row by the received detection data. Also, the data memory unit 52 updates, when the detection data Dout corresponding to the respective pixels Px in the second row is received, the detection data Dout in a memory region of the first row by the received detection data. The data memory unit 52 updates, when the detection data Dout corresponding to the respective pixels Px in the 539 th row is received, the detection data Dout in a memory region of the 54 th row by the received detection data. Further, the data memory unit 52 updates, when the detection data Dout corresponding to the respective pixels Px in the 540 th row is received, the detection data Dout in a memory region of the 54 th row by the received detection data.

The correction unit 53 of the control unit 50 reads, when generating the display data Din, gradation data for every pixel Px transmitted from the adjustment unit 51 and the detection data Dout corresponding to the pixel Px. The correction unit 53 performs addition-subtraction on the gradation data for every pixel Px based on the detection data Dout corresponding to the pixel Px and outputs the display data Din for every pixel Px.

According to the above-described third embodiment, the following effects can be obtained other than effects described in the above (1) to (6) and (8).

(9) compared to a configuration in which the data memory unit 52 includes a memory region of m-rows×n-columns, memory capacity of the data memory unit 52 can be saved.

(10) a film property of respective thin films that constitute the current control transistor Tr3 often dominates an amount of variation in the threshold voltage Vth and such film properties of the thin film are close to each other in mutually adjacent rows. Therefore, in the mutually adjacent rows, the amount of variations in the threshold voltages Vth it likely to be close. In this regard, according to the third embodiment, in mutually adjacent rows, the detection data Dout for one row is used as detection data Dout for the other row. As a result, when the detection data Dout is updated for all of the pixels Px, the period for updating the detection data Dout is shortened. Accordingly, when an amount of variation in the threshold voltage is large in unit time, degradation of image which is displayed can effectively avoided.

(Modification)

The above-described embodiments can be modified and implemented as follows. The detecting object row according to the second embodiment and the third embodiment may be shifted for more than or equal to two rows along the scanning direction when every single frame is displayed. In this case, assuming the amount of shift of the detecting object row when every single frame is displayed is set as Sf, the data memory unit 52 of the third embodiment includes a memory region having m/Sf row×n-column and respective Sf number of pixels Px arranged along the column direction correspond to one memory region.

The Sf number of pixels Px arranged along the column direction may be set as one group and the first row in the respective groups may be set as a detecting object row in the third embodiment. In other words, the detecting object row may have a configuration in which the detecting object row is repeatedly shifted at every frame in the order of the first row, 11th row, 21st row, . . . , 511th row, 521st row, 531st row. Also, the detecting object row may have a configuration in which it is not limited to the first row, instead specific row in the respective groups is detected as a detecting object row, the detection data Dout of the respective rows in the group is always represented by the detection data Dout of specific row.

In the first embodiment and the second embodiment, the detection data Dout obtained in a period where the present frame is displayed may be treated as detection data corresponding to all of rows in a period where the next frame is displayed. In this case, the data memory unit 52 includes one memory region having one row×n column and respective m number of pixels Px is set to correspond to one memory region. For example, when the operating temperature of the current control transistor Tr3 dominates an amount of variation in the threshold voltage Vth, the amount of variations in the threshold voltages Vth in all of the current control transistors Tr3 are close to each other. In this respect, according to the above-described configuration, since the detection data Dout for one row is used for the detection data Dout for the other rows as well, effects similar to the above-described (9) and (10) becomes significant.

The detecting object row may be set in the same row in every frame. Further, the detecting object row may be set randomly for every frame. To set the detecting object row randomly, for example, a random function that generates random numbers at every frame from the first frame to the m th frame is employed in the control unit 50. Then, a configuration may be used where a timing at which the shift-standby section is outputted with the detection shift clock Clkr and a timing at which the mask released section is outputted with the mask pulse signal MP are synchronized to each other and these timings are delayed, from the start pulse signal SP2, for a period responding to the generated random number.

Two or more detecting object rows may be used at every frame. In this case, in the detection shift clock signal Clkr, two shift-standby sections are outputted at mutually different timings. Also, in the mask pulse signal MP, two mask released sections are outputted at mutually different timings. Moreover, a timing at which each of two shift-standby sections are outputted and a timing at which each of two mask released sections are outputted are synchronized to each other.

For example, when the display device is activated, in a period other than a period where a single frame is displayed, such as when the display device is stopped and then resumed, the threshold detecting operation may be performed to the respective pixel circuits PCC of all rows or a part of rows.

The detection-use voltage Vm applied during a single threshold detecting operation may be different for each data line Ld. In this case, in the threshold detecting operation, each of a plurality of data lines Ld may be connected to the analog power supply 70 via mutually different wirings. Alternatively, the detection-use voltage Vm, as a digital data, may be supplied to the data line Ld from the data driver circuit 40.

The data line Ld to which the detection-use voltage Vm is applied during a single threshold detecting operation may be a part of all data lines Ld. In this case, in a single threshold detecting operation, only the part of data line Ld to which the detection-use voltage Vm is applied, is connected to the analog power supply 70 via the detection voltage switch SWs.

According to the above-described embodiment, the threshold voltage Vth as a property of the current control transistor Tr3 is detected and the display voltage Vd is corrected based on the detected threshold voltage Vth. However, it is not limited to this configuration, and instead a current amplification factor β as a property of the current control transistor Tr3 may be detected, and the display voltage Vd may be corrected based on the detected current amplification factor β. Moreover, as a property of the current control transistor Tr3, both the threshold voltage Vth and the current amplification factor β may be detected. In other words, detecting object in the threshold detecting operation may be a parameter that influences the drive current supplied to the organic EL element OEL among device properties of the current control transistor Tr3.

Regarding the correction of the display voltage Vd, in addition to the device property of the current control transistor Tr3, an emission property of the organic EL element OEL such as light luminance may be used.

The configuration of the pixel circuit PCC is not limited to the above-described configuration. As long as the circuit is configured such that a drive current is supplied to the organic EL element OEL via the current control transistor, the types of element included in the pixel circuit PCC and the circuit configuration may be determined arbitrarily. Further, the light emitting element is not limited to an organic EL element. The light emitting element may be an element that emits light by being supplied the drive current via the current control transistor such as an inorganic EL element or a LED.

Device characteristics such as threshold voltage in the current control transistor vary due to aging, etc. Therefore, even when the voltage between gate and source of the current control transistor is the same, drive current supplied through the current control transistor may become a different value in a short period of time. As a result, depending on a change in the device characteristics of a current drive transistor, an accuracy of gradation control of the light luminance of the organic EL element is decreased so that image quality such as luminance of the image displayed by the display device, contrast and color gradation may change.

The technique of the present disclosure has an object to provide a display device capable of suppressing variation in the image quality due to a change in the device characteristics of a pixel circuit that supplies drive current to the light emitting element, and a display method.

An aspect of a display device according to the present disclosure is provided with a plurality of light emitting elements, a plurality of pixel circuits each including a transistor, supplying a drive current to the respective light emitting elements, a plurality of scan lines connected to the pixel circuits, a plurality of data lines connected to the pixel circuits, a select driver that selects any one of the plurality of scan lines to be a selected object, and a control unit that controls a drive of the select driver.

The control unit repeatedly executes a gradation display operation, a non-gradation display operation and a detecting operation in this order. In the gradation display operation, the scan lines are sequentially selected one by one to be a selected object and a gradation display voltage is applied to the pixel circuit connected to the selected object via the data line so as to make corresponding light emitting element to be in a gradation display state. In the non-gradation display operation, the scan lines are sequentially selected one by one to be a selected object and a non-gradation display voltage is applied to the pixel circuit connected to the selected object via the data line so as to set the corresponding light emitting element to a non-gradation display state. In the detecting operation, a part of the plurality of scan lines are selected to be a detecting object in the non-gradation display operation and a property of the transistor of the pixel circuit connected to the detecting object is detected via the data line. The control unit is configured to correct the gradation display voltage by using a detection result obtained by the detecting operation.

An aspect of a display device according to the present disclosure includes a gradation display operation, a non-gradation-display operation and a detecting operation which are repeatedly executed in this order and correcting the gradation-display voltage by using a detection result obtained by the detecting operation. The gradation display operation is an operation in which a plurality of scan lines (to each of which a pixel circuit is connected including a transistor supplying a drive current to a light emitting element) are sequentially selected one by one to be a selected object, and a gradation display voltage is applied to the pixel circuit connected to the selected object via the data line so as to set the corresponding light emitting element to a gradation display state. The non-gradation display operation is an operation in which the scan lines are sequentially selected one by one to be a selected object and a non-gradation display voltage is applied to the pixel circuit connected to the selected object via the data line so as to set the corresponding light emitting element to a non-gradation display state. The detecting operation is an operation in which a part of the plurality of scan lines are selected to be a detecting object in the non-gradation display operation and a property of the transistor of the pixel circuit connected to the detecting object is detected via the data line.

According to the above-described configuration, a property of the transistor in the pixel circuit is detected by the detecting operation and the gradation display voltage applied to the pixel circuit is corrected based on the detection result. Therefore, when the property of the transistor varies, the gradation display voltage is corrected based on the variation in the property of the transistor. As a result, variation in the image due to variation in the property of the transistor can be avoided and further, degradation of the image due to variation in the property of the transistor can be avoided.

Moreover, since the gradation display operation, the non-gradation display operation and the detection operation are repeatedly executed in this order, for example, compared to a configuration in which the detecting operation is executed only when the display device is activated, a time difference between a timing of the gradation display operation and a timing of the detecting operation becomes shorter. Hence, when the property of the transistor varies significantly in a short period of time, degradation of the image can be effectively avoided. Moreover, the detection operation is executed only for a pixel circuit connected to a part of the scan lines. Accordingly, compared to a configuration in which a detecting operation is executed for all pixel circuits in one detecting operation, the time required for executing one detecting operation becomes shorter. Hence, a non-displayed period becoming longer than necessary because of the time required for the detecting operation can be avoided. As a result, the detecting operation can be prevented from influencing the display performance itself of the image in the display device.

According to another aspect of the display device of the present disclosure, the control unit is configured to change the detecting object at every detecting operation. According to the above-described configuration, the pixel circuit from which the property of the transistor is detected, is set as the detecting object and the detecting object is changed in every detecting operation. Therefore, compared to a configuration in which the same detecting object is used in every detecting operation, the range of the detecting object can be expanded. Accordingly, when the property of the transistor is the same between a pixel circuit to be detected and a pixel circuit to which corrected gradation display voltage is applied, degradation of the image quality can be avoided in an extended range.

Furthermore, when variation in the property of the transistor depends on the manufacturing process of the transistor or an operating temperature of the transistor, the degree of the variation may be similar between mutually different pixel circuits. Hence, when the gradation display voltage is corrected for one pixel circuit, detection results of the other pixel circuit may be used. In this respect, in the above-described configuration, since the range of the detecting object is extended, when the gradation display voltage is corrected for one pixel circuit, candidates of the detection result used for the correction are increased. As a result, the detection result can be shared between pixel circuits in which variations in the property of the transistors are expected to be close to each other, whereby the accuracy of the correction for the gradation display operation can be enhanced.

According to another aspect of the display device of the present disclosure, the control unit is configured to set the number of detecting objects for one detecting operation to be one line. According to the above-described configuration, in the one detecting operation, the property of the transistor is detected only for a pixel circuit which is connected to a single scan line. Accordingly, compared to a configuration in which the number of detecting objects to be selected in one detecting operation is more than or equal to two lines, the time required for the one detecting operation can be shorter. As a result, the detecting operation can be prevented from influencing the display performance of the image in the display device.

According to another aspect of the display device of the present disclosure, the control unit is configured to switch the detecting object to be an adjacent object at every detecting operation. According to the above-described configuration, since the location of the pixel circuit from which the property of the transistor is detected is switched to an adjacent object at every detecting operation, compared to a configuration in which the detecting object in the detecting operation is switched to an object being separated by two lines at every detecting operation, degradation of the image can be avoided precisely.

According to the other aspect of the display device of the present disclosure, the control unit is configured to switch the detecting object to be an object being separated by a plurality of lines at every detecting operation. According to the above-described configuration, compared to a configuration in which the detecting object is switched to an immediately adjacent object at every detecting operation, location of the pixel circuit from which the characteristic of the transistor is detected per unit time is dispersed. Therefore, in a case where variation in the property of the transistor is dotted in a wide area, compared to a configuration in which the detecting object is switched to an immediately adjacent object at every detecting operation, degradation of the image can be precisely avoided.

According to the other aspect of the display device of the present disclosure, the control unit is configured to divide a plurality of scan lines into a plurality of scan line groups each having a plurality of scan lines which are adjacent to each other, store data concerning the detection result to correspond with the scan line group that includes the detecting object, switch the detecting object for every scan line group at every detecting operation and correct the gradation display voltage to the pixel circuit connected to the scan line group by using the data corresponding with the scan line group.

According to the above-described configuration, data concerning the detection result of the property of the transistor is stored for every scan line group. Hence, data concerning the detection result of the characteristic of the transistor requires less memory capacity for the memory unit as compared to a configuration in which the data is stored for every scan line. Also, a period for updating the data becomes shorter.

According to another aspect of the display device of the present disclosure, the select driver is configured to switch a candidate of the selected object sequentially at a display period in each of the gradation display operation and the non-gradation display operation and switch a candidate of the detecting object sequentially at a detecting period, and the control unit is configured to shorten the detecting period to be shorter than the display period.

According to the above-described configuration, when one scan line is selected as an object, switching of the candidate of the object is processed sequentially in a plurality of scan lines. In this case, since a period of the switching in the detecting operation is shorter than a period of the switching in the other operations, a time required for selecting a specific object becomes shorter, compared to the other operations. As a result, since a time required for one detecting operation becomes shorter, a non-displayed state can be prevented from becoming longer than necessary due to a required period of the detecting operation.

According to the display device and the display method of the present disclosure, variation in the image quality due to change in the device characteristics of the pixel circuit that supplies drive current to the light emitting element can be avoided.

Obviously, numerous modifications and variations of the present invention are possible in light of the above teachings. It is therefore to be understood that within the scope of the appended claims, the invention may be practiced otherwise than as specifically described herein.

What is claimed is:

1. A display device, comprising:
a plurality of light emitting elements;
a plurality of pixel circuits each including a transistor and configured to supply a drive current to each of the light emitting elements;
a plurality of scan lines connected to the pixel circuits;
a plurality of data lines connected to the pixel circuits;
a select driver configured to select one of the scan lines; and
a control unit configured to control driving of the select driver,
wherein the control unit is configured to repeatedly execute a set of operations including a gradation display operation, a non-gradation display operation and a detecting operation in an order thereof,
the gradation display operation is an operation in which the scan lines are sequentially selected one by one, and a gradation display voltage is applied to the pixel circuit connected to a selected scan line via one of the data lines such that a corresponding light emitting element has a gradation display state,
the non-gradation display operation is an operation in which the scan lines are sequentially selected one by one, and a non-gradation display voltage is applied to the pixel circuit connected to a selected scan line via one of the data lines such that a corresponding light emitting element has a non-gradation display state, and
the detecting operation is an operation in which one or more scan lines are selected in the non-gradation display operation, and a characteristic of the transistor of the pixel circuit connected to the one or more scan lines is detected via one of the data lines to correct the gradation display voltage based on a detection result of the detecting operation.

2. The display device according to claim 1, wherein the control unit is configured to control the select driver to select different scan lines in every detecting operation.

3. The display device according to claim 1, wherein the control unit is configured to control the select driver to select one scan line in one detecting operation.

4. The display device according to claim 3, wherein the control unit is configured to control the select driver to select one scan line adjacent to the one selected in a previous detecting operation.

5. The display device according to claim 3, wherein the control unit is configured to control the select driver to select one scan line separated by a plurality of lines from the one selected in a previous detecting operation.

6. The display device according to claim 5, wherein the control unit is configured to divide the plurality of scan lines into a plurality of scan line groups each including scan lines adjacent to each other, store data including the detection result in correspondence to the scan line group that includes the scan line selected in the detecting operation, control the select driver to select different scan line groups in every detecting operation, and correct the gradation display voltage applied to the pixel circuit connected to the scan line group based on the data corresponding to each scan line group.

7. The display device according to claim 6, wherein the select driver is configured to switch a candidate for selection sequentially at a display period in each of the gradation display operation and the non-gradation display operation, and switch a candidate for selection sequentially at a detecting period in the detecting operation, and the control unit is configured to set the detecting period as being shorter than the display period.

8. The display device according to claim 2, wherein the control unit is configured to control the select driver to select one scan line in one detecting operation.

9. The display device according to claim 8, wherein the control unit is configured to control the select driver to select one scan line adjacent to the one selected in a previous detecting operation.

10. The display device according to claim 8, wherein the control unit is configured to control the select driver to select one scan line separated by a plurality of lines from the one selected in a previous detecting operation.

11. The display device according to claim 10, wherein the control unit is configured to divide the plurality of scan lines into a plurality of scan line groups each including scan lines adjacent to each other, store data including the detection result in correspondence to the scan line group that includes the scan line selected in the detecting operation, control the select driver to select different scan line groups in every detecting operation, and correct the gradation display voltage applied to the pixel circuit connected to the scan line group based on the data corresponding to each scan line group.

12. The display device according to claim 11, wherein the select driver is configured to switch a candidate for selection sequentially at a display period in each of the gradation display operation and the non-gradation display operation, and switch a candidate for selection sequentially at a detecting period in the detecting operation, and the control unit is configured to set the detecting period as being shorter than the display period.

13. A display method, comprising:
repeatedly executing a set of operations including a gradation display operation, a non-gradation display operation and a detecting operation in an order thereof; and
correcting a gradation display voltage based on a detection result of the detecting operation,
wherein the gradation display operation is an operation in which the scan lines are sequentially selected one by one, and a gradation display voltage is applied to the pixel circuit connected to a selected scan line via one of the data lines such that a corresponding light emitting element has a gradation display state,
the non-gradation display operation is an operation in which the scan lines are sequentially selected one by one, and a non-gradation display voltage is applied to the pixel circuit connected to a selected scan line via one of the data lines such that a corresponding light emitting element has a non-gradation display state, and
the detecting operation is an operation in which one or more scan lines are selected in the non-gradation display operation, and a characteristic of the transistor of the pixel circuit connected to the one or more scan lines is detected via one of the data lines to correct the gradation display voltage based on a detection result of the detecting operation.

14. The method according to claim 13, wherein different scan lines are selected in every detecting operation.

15. The method according to claim 13, wherein one scan line is selected in one detecting operation.

16. The method according to claim 15, wherein one scan line adjacent to the one selected in a previous detecting operation is selected in every detecting operation.

17. The method according to claim 15, wherein the control unit is configured to control the select driver to select one scan line separated by a plurality of lines from the one selected in a previous detecting operation.

18. The method according to claim 17, wherein the plurality of scan lines is divided into a plurality of scan line groups each including scan lines adjacent to each other, data including the detection result are stored in correspondence to the scan line group that includes the scan line selected in the detecting operation, different scan line groups are selected in every detecting operation, and the gradation display voltage applied to the pixel circuit connected to the scan line group is corrected based on the data corresponding to each scan line group.

19. The display device according to claim 18, wherein a candidate for selection is switched sequentially at a display period in each of the gradation display operation and the non-gradation display operation, and a candidate for selection is switched sequentially at a detecting period in the detecting operation, and the detecting period is shorter than the display period.
